(19) United States
(12) Patent Application Publication
(10) Pub. No.: US 2026/0198084 A1
(43) Pub. Date: Jul. 9, 2026

(54) INTEGRATED CIRCUIT DEVICE

(71) Applicant: Samsung Electronics Co., Ltd., Suwon-si (KR)

(72) Inventors: Sangmin Cho, Suwon-si (KR); Subin Lee, Suwon-si (KR); Jeongyong Choi, Suwon-si (KR); Minju Kim, Suwon-si (KR); Joungkil Park, Suwon-si (KR)

(21) Appl. No.: 19/264,518

(22) Filed: Jul. 9, 2025

(30) Foreign Application Priority Data
Jan. 3, 2025 (KR) 10-2025-0001181

(51) Int. Cl. H10D 84/85; H10D 84/01

(52) U.S. Cl. CPC H10D 84/851; H10D 84/0167; H10D 84/017; H10D 84/0186

(57) ABSTRACT

An integrated circuit device includes a fin-type active region extending in a first lateral direction, a channel region on the fin-type active region, a gate line surrounding the channel region, a source/drain region contacting the channel region on the fin-type active region, a source/drain contact connected to the source/drain region on the source/drain region, a source/drain via contact protruding from a first upper surface of the source/drain contact in a vertical direction and integrally connected to the source/drain contact, and a source/drain contact extension contacting the first upper surface of the source/drain contact at a position spaced apart from the source/drain via contact in a second lateral direction that is perpendicular to the first lateral direction, the source/drain contact extension having a second upper surface at a second vertical level that is farther from the source/drain region than a first vertical level of the first upper surface.

### CROSS-REFERENCE TO RELATED APPLICATION

This application is based on and claims priority under 35 U.S.C. § 119 to Korean Patent Application No. 10-2025-0001181, filed on Jan. 3, 2025, in the Korean Intellectual Property Office, the disclosure of which is incorporated by reference herein in its entirety.

### BACKGROUND

As the downscaling of IC devices has rapidly progressed, it is required that the IC devices

have not only a high operating speed but also high operating accuracy. Thus, various research is being conducted to provide an IC device having a structure capable of exhibiting optimal performance and improving reliability.

### SUMMARY

The present disclosure relates to an integrated circuit (IC) device, and more particularly, to an IC device including a field-effect transistor (FET).

The present disclosure provides an integrated circuit (IC) device, which includes a plurality of wiring structures arranged within a reduced area due to downscaling and has a structure capable of ensuring reliability and simplifying a manufacturing process.

According to an aspect of the present disclosure, an IC device includes a fin-type active region extending in a first lateral direction, a channel region on the fin-type active region, a gate line surrounding the channel region, a source/drain region on the fin-type active region, the source/drain region being in contact with the channel region, a source/drain contact on the source/drain region, the source/drain contact being configured to be connected to the source/drain region, a source/drain via contact protruding from a first upper surface of the source/drain contact in a vertical direction, the source/drain via contact being integrally connected to the source/drain contact; and a source/drain contact extension in contact with the first upper surface of the source/drain contact at a position spaced apart from the source/drain via contact in a second lateral direction, the source/drain contact extension having a second upper surface that is at a second vertical level, wherein the second lateral direction is perpendicular to the first lateral direction, and the second vertical level is farther from the source/drain region than a first vertical level of the first upper surface.

According to another aspect of the present disclosure, an IC device includes a pair of fin-type active regions each extending in a first lateral direction, the pair of fin-type active regions being parallel to each other,
a plurality of channel regions on the pair of fin-type active regions, a plurality of gate lines extending in a second lateral direction on the pair of fin-type active regions, wherein the second lateral direction is perpendicular to the first lateral direction, a pair of source/drain regions on the pair of fin-type active regions, a source/drain contact on at least one source/drain region selected from the pair of source/drain regions, the source/drain contact being configured to be connected to the at least one source/drain region, a source/drain via contact protruding from a first upper surface of the source/drain contact in a vertical direction, the source/drain via contact being integrally connected to the source/drain contact, and a source/drain contact extension in contact with the first upper surface of the source/drain contact at a position spaced apart from the source/drain via contact in the second lateral direction, the source/drain contact extension having a second upper surface that is at a second vertical level, wherein the second vertical level is farther from the source/drain region than a first vertical level of the first upper surface.

According to another aspect of the present disclosure, an IC device includes a fin-type active region extending in a first lateral direction, a channel region on the fin-type active region, a gate line surrounding the channel region, a source/drain region on the fin-type active region, the source/drain region being in contact with the channel region, a source/drain contact on the source/drain region, the source/drain contact being connected to the source/drain region, a source/drain via contact protruding from a first upper surface of the source/drain contact in a vertical direction, the source/drain via contact being integrally connected to the source/drain contact, a source/drain contact extension in contact with the first upper surface of the source/drain contact at a position spaced apart from the source/drain via contact in a second lateral direction, the source/drain contact extension having a second upper surface that is at a second vertical level, wherein the second lateral direction is perpendicular to the first lateral direction, and the second vertical level is farther from the source/drain region than a first vertical level of the first upper surface, a gate contact protruding from a third upper surface of the gate line in the vertical direction, the gate contact being integrally connected to the gate line, and a gate extension in contact with the third upper surface of the gate line at a position spaced apart from the gate contact in the second lateral direction, the gate extension having a fourth upper surface that is at a higher vertical level than the third upper surface.

### BRIEF DESCRIPTION OF THE DRAWINGS

Implementations will be more clearly understood from the following detailed description taken in conjunction with the accompanying drawings in which:

FIG. 1 is a schematic plan view of an example of a cell block of an integrated circuit (IC) device according to implementations;

FIG. 2 is a plan layout diagram of some components of an IC device according to implementations;

FIG. 3 is a cross-sectional view of a configuration corresponding to each of a cross-section taken along line X1-X1′ of FIG. 2 and a cross-section taken along line X2-X2′ of FIG. 2;

FIG. 4 is a cross-sectional view taken along line Y1-Y1′ of FIG. 2;

FIG. 5 is a cross-sectional view taken along line Y2-Y2′ of FIG. 2;

FIG. 6 is an enlarged cross-sectional view of a portion denoted by “EX1” in FIG. 3;

FIG. 7 is an enlarged cross-sectional view of a portion denoted by “EX2” in FIG. 4;

FIG. 8 is a cross-sectional view of an IC device according to implementations;

FIG. 9 is a cross-sectional view of an IC device according to implementations;

FIG. 10 is a block diagram of an IC device according to implementations;

FIGS. 11A to 31C are cross-sectional views illustrating a process sequence of a method of manufacturing an IC device, according to implementations; and

FIGS. 32A to 38 are diagrams illustrating a process sequence of a method of manufacturing an IC device, according to implementations.

### DETAILED DESCRIPTION

Hereinafter, implementations will be described in detail with reference to the

accompanying drawings. The same reference numerals are used to denote the same elements in the drawings, and repeated descriptions thereof will be omitted.

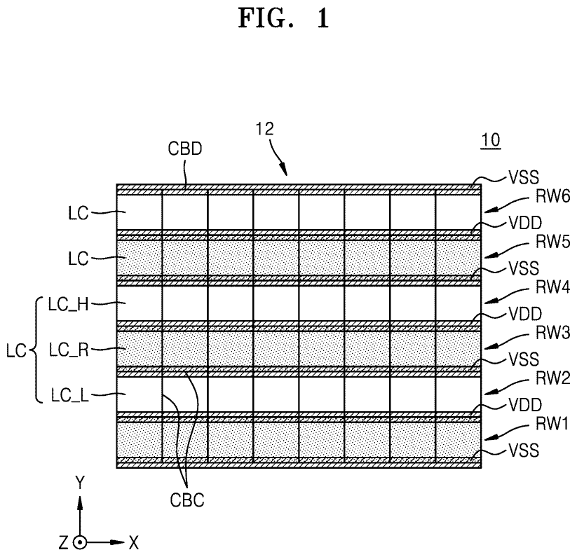

FIG. 1 is a schematic plan view of an example of a cell block 12 of an integrated circuit (IC) device 10 according to implementations.

Referring to FIG. 1, the cell block 12 of the IC device 10 may include a plurality of cells LC, which include circuit patterns configured to constitute various circuits. The plurality of cells LC may be arranged in a matrix form in a widthwise direction (X direction in FIG. 1) and a height direction (Y direction in FIG. 1) in the cell block 12.

Each of the plurality of cells LC may include a circuit pattern having a layout designed according to a place-and-route (PnR) technique to perform at least one logic function. The plurality of cells LC may perform various logic functions. In implementations, the plurality of cells LC may include a plurality of standard cells. In implementations, at least some of the plurality of cells LC may perform the same logic function. In other implementations, at least some of the plurality of cells LC may perform different logic functions.

The plurality of cells LC may include various kinds of logic cells including a plurality of circuit elements. For example, each of the plurality of cells LC may include an AND, a NAND, an OR, a NOR, an exclusive OR (XOR), an exclusive NOR (XNOR), an inverter (INV), an adder (ADD), a buffer (BUF), a delay (DLY), a filter (FIL), a multiplexer (MXT/MXIT), an OR/AND/INVERTER (OAI), an AND/OR (AO), an AND/OR/INVERTER (AOI), a D-flip-flop, a reset flip-flop, a master-slave flip-flop, and/or a latch, without being limited thereto.

In the cell block 12, at least some of the plurality of cells LC that form one row RW1, RW2, RW3, RW4, RW5, or RW6 in the widthwise direction (X direction in FIG. 1) may have the same width as each other. Also, at least some of the plurality of cells LC that form one row RW1, RW2, RW3, RW4, RW5, or RW6 may have the same height as each other. However, the present disclosure is not limited to those illustrated in FIG. 1, and at least some of the plurality of cells LC that form one row RW1, RW2, RW3, RW4, RW5, or RW6 may have different widths and heights from each other.

An area of each of the plurality of cells LC included in the cell block 12 of the IC device 10 may be defined by a cell boundary CBD. A cell boundary contact portion CBC where respective cell boundaries CBD of two cells LC that are adjacent to each other in the widthwise direction (X direction in FIG. 1) or the height direction (Y direction in FIG. 1), from among the plurality of cells LC, meet each other may be between the two adjacent cells LC.

In implementations, from among the plurality of cells LC that form one row RW1, RW2, RW3, RW4, RW5, or RW6, two cells LC that are adjacent to each other in the widthwise direction may contact each other at the cell boundary contact portion CBC without a distance therebetween. In other implementations, from among the plurality of cells LC that form one row RW1, RW2, RW3, RW4, RW5, or RW6, two cells LC that are adjacent to each other in the widthwise direction may be spaced a predetermined distance apart from each other.

In implementations, from among the plurality of cells LC that form one row RW1, RW2, RW3, RW4, RW5, or RW6, two adjacent cells may perform the same function as each other. In this case, the two adjacent cells LC may have the same structure as each other. In other implementations, from among the plurality of cells LC that form one row RW1, RW2, RW3, RW4, RW5, or RW6, two adjacent cells may perform different functions from each other.

In implementations, one cell LC, which is selected from the plurality of cells LC included in the cell block 12 of the IC device 10, may have a symmetrical structure to another cell LC, which is adjacent to the selected cell LC in the height direction (Y direction in FIG. 1), about the cell boundary contact portion CBC therebetween. For example, a reference logic cell LC_R in a third row RW3 may have a symmetrical structure to a lower logic cell LC_L in a second row RW2 about the cell boundary contact portion CBC therebetween. Also, the reference logic cell LC_R in the third row RW3 may have a symmetrical structure to an upper logic cell LC_H in a fourth row RW4 about the cell boundary contact portion CBC therebetween. Although FIG. 1 illustrates an example in which the cell block 12 including six rows RW1, RW2, RW3, RW4, RW5, and R6, the present disclosure is not limited thereto. The cell block 12 may include various numbers of rows, which are selected as needed, and one row may include various numbers of cells, which are selected as needed.

A selected one of a plurality of ground lines VSS and a plurality of power lines VDD may be between a plurality of rows RW1, RW2, RW3, RW4, RW5, and RW6, each of which includes a plurality of cells LC arranged in a line in the widthwise direction (X direction in FIG. 1). The plurality of ground lines VSS and the plurality of power lines VDD may each extend in a first lateral direction (X direction) and may be alternately arranged apart from each other in a second lateral direction (Y direction). The second lateral direction (Y direction) may be a direction perpendicular to the first lateral direction (X direction). Accordingly, each of the plurality of ground lines VSS and the plurality of power lines VDD may be arranged to overlap the cell boundary CBD of the cell LC in the second lateral direction (Y direction).

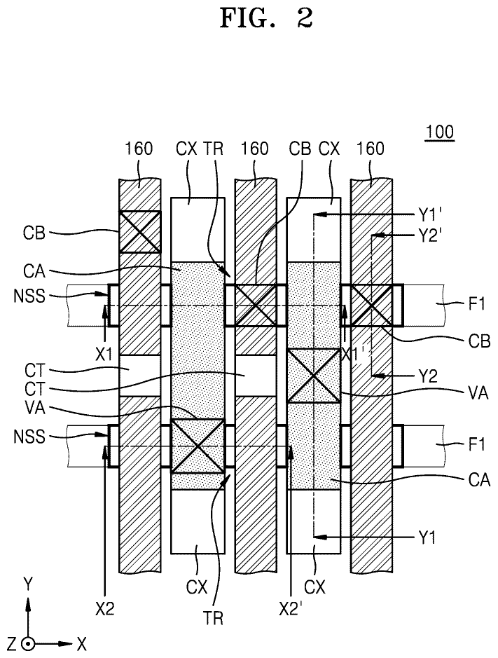

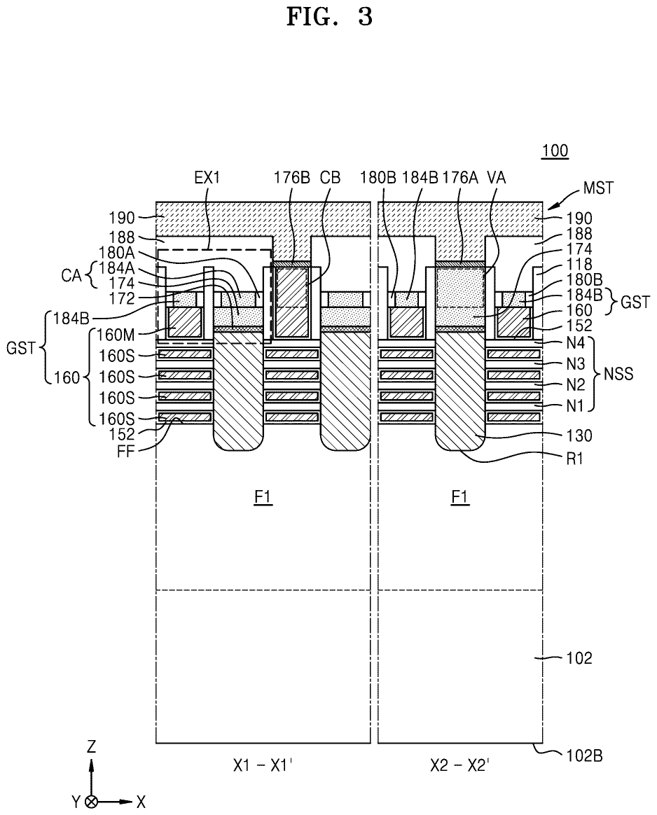

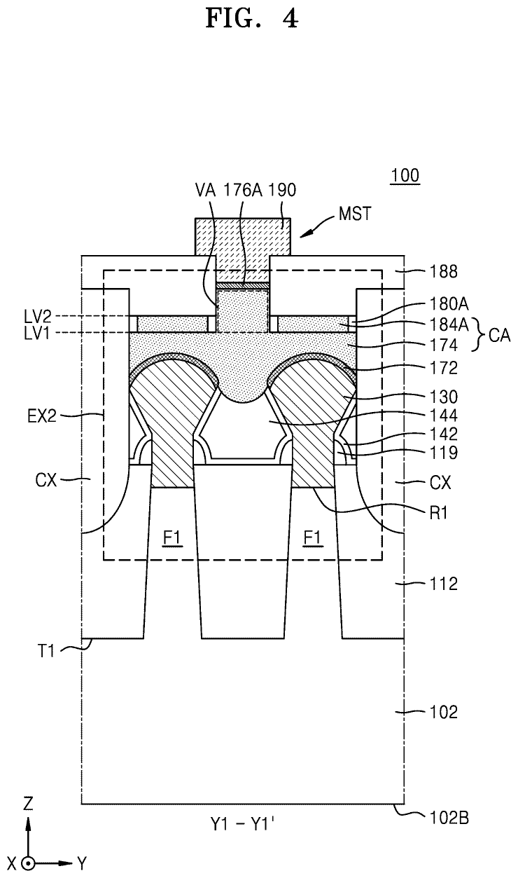

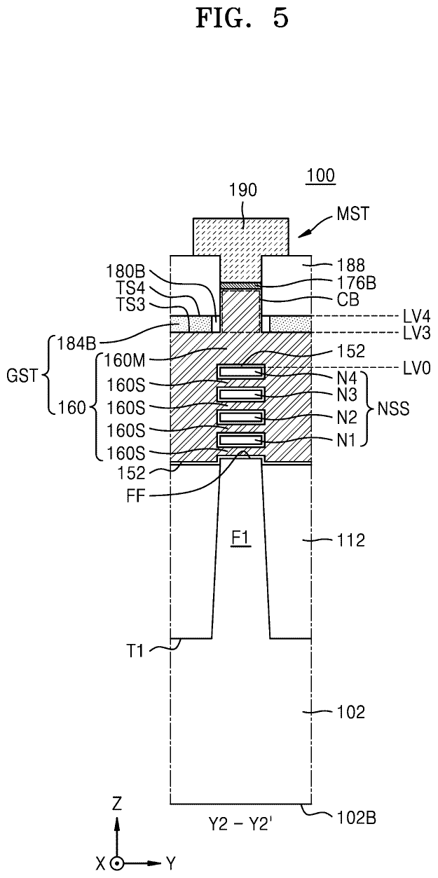

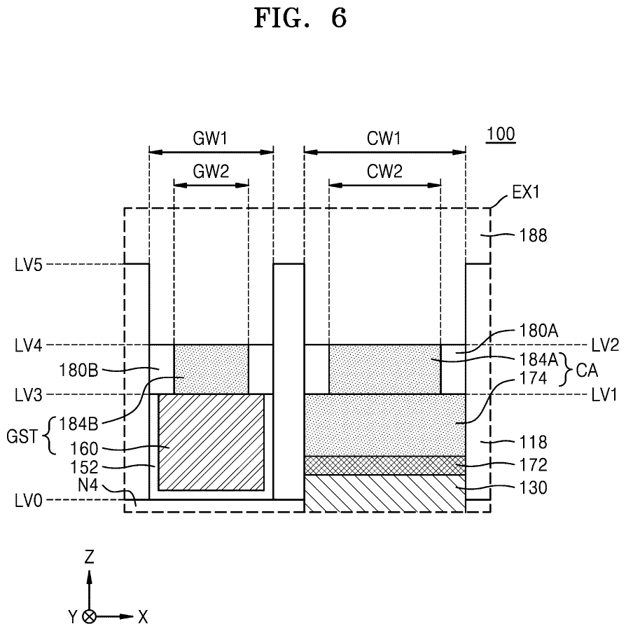

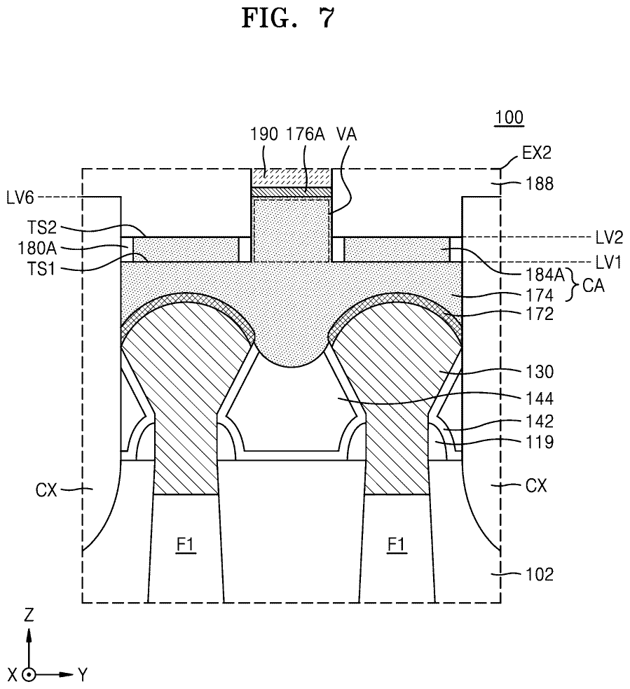

FIG. 2 is a plan layout diagram of some components of an integrated circuit (IC) device 100 according to implementations. FIG. 3 is a cross-sectional view of a configuration corresponding to each of a cross-section taken along line X1-X1′ of FIG. 2 and a cross-section taken along line X2-X2′ of FIG. 2. FIG. 4 is a cross-sectional view taken along line Y1-Y1′ of FIG. 2. FIG. 5 is a cross-sectional view taken along line Y2-Y2′ of FIG. 2. FIG. 6 is an enlarged cross-sectional view of portion denoted by “EX1” in FIG. 3. FIG. 7 is an enlarged cross-sectional view of portion denoted by “EX2” in FIG. 4. The IC device 100 including field-effect transistor (FETs) TR having a gate-all-around structure including a channel region of a nanowire or nanosheet type and a gate surrounding the channel region will now be described with reference to FIGS. 2 to 7. Components of the IC device 100 that is described with reference to FIGS. 2 to 7 may constitute some of the plurality of cells LC illustrated in FIG. 1.

Referring to FIGS. 2 to 7, the IC device 100 may include a plurality of fin-type active regions F1, a plurality of nanosheet stacks NSS, a plurality of gate lines 160, and a plurality of source/drain regions 130. The plurality of fin-type active regions F1 may protrude over a substrate 102 and extend lengthwise in a first lateral direction (X direction). The plurality of nanosheet stacks NSS may be located over and apart from the plurality of fin-type active regions F1 in a vertical direction (Z direction) and face fin top surfaces FF of the fin-type active regions F1. The plurality of gate lines 160 may surround the plurality of nanosheet stacks NSS. Each of the plurality of source/drain regions 130 may be between two adjacent ones of the plurality of gate lines 160. A source/drain region in the present disclosure can refer to either a source region or a drain region.

The plurality of fin-type active regions F1 may be spaced apart from each other in a second lateral direction (Y direction). Each of the plurality of gate lines 160 may be surrounded by a gate dielectric film 152. The plurality of gate lines 160, the plurality of nanosheet stacks NSS, and the plurality of source/drain regions 130 may constitute a plurality of field-effect transistors (FETs) TR.

The substrate 102 may include a semiconductor, such as silicon (Si) or germanium (Ge), or a compound semiconductor, such as silicon germanium (SiGe), silicon carbide (SiC), gallium arsenide (GaAs), indium arsenide (InAs), indium gallium arsenide (InGaAs), or indium phosphide (InP). As used herein, each of the terms “SiGe,” “SiC,” “GaAs,” “InAs,” “InGaAs,” and “InP” refers to a material including elements included therein, without referring to a chemical formula representing a stoichiometric relationship. The substrate 102 may include a conductive region, for example, a doped well or a doped structure.

A trench T1 defining the fin-type active region F1 may be formed in the substrate 102. The trench T1 may be filled by a device isolation film 112. The device isolation film 112 may include a silicon oxide film. A plurality of gate lines 160 may be arranged on the plurality of fin-type active regions F1 and a plurality of device isolation films 112. Each of the plurality of gate lines 160 may extend lengthwise in a second lateral direction (Y direction) that is perpendicular to the first lateral direction (X direction). The plurality of nanosheet stacks NSS may be respectively on fin top surfaces FF of the fin-type active regions F1 in regions where the fin-type active regions F1 intersect the plurality of gate lines 160.

Each of the plurality of nanosheet stacks NSS may include at least one nanosheet. As illustrated in FIGS. 3 and 5, each of the plurality of nanosheet stacks NSS may include first to fourth nanosheets N1, N2, N3, and N4, which overlap each other in the vertical direction (Z direction) on the fin-type active region F1. Each of the first to fourth nanosheets N1, N2, N3, N4 included in the nanosheet stack NSS may provide a channel region. As used herein, the term “nanosheet” refers to a conductive structure having a cross-section that is substantially perpendicular to a direction in which current flows. The nanosheet may be interpreted as including a nanowire. As used herein, each of the first to fourth nanosheets N1, N2, N3, N4 and the nanosheet stack NSS including the first to fourth nanosheets N1, N2, N3, and N4 may be referred to as a channel region.

In implementations, each of the first to fourth nanosheets N1, N2, N3, and N4 included in the nanosheet stack NSS may include a Si layer, a SiGe layer, or a combination thereof. For example, each of the first to fourth nanosheets N1, N2, N3, and N4 may include a Si layer.

The first to fourth nanosheets N1, N2, N3, and N4 may be at different vertical distances (Z-directional distances) from the fin top surface FF of the fin-type active region F1. Each of the plurality of gate lines 160 may surround the first to fourth nanosheets N1, N2, N3, and N4 of the nanosheet stack NSS, which overlap each other in the vertical direction (Z direction).

Although FIG. 2 illustrates a case in which the nanosheet stack NSS has a substantially tetragonal plane shape, without being limited thereto. The nanosheet stack NSS may have various plane surfaces according to a plane shape of each of the fin-type active region F1 and the gate line 160. The plurality of nanosheet stacks NSS may be spaced apart from each other in the first lateral direction (X direction) on one fin-type active region F1. The present implementation pertains to a configuration in which the plurality of nanosheet stacks NSS and the plurality of gate lines 160 are arranged on one fin-type active region F1, and the plurality of nanosheet stacks NSS are arranged in a line in the first lateral direction (X direction) on one fin-type active region F1. However, the number of nanosheet stacks NSS and the number of gate lines 160 on one fin-type active region F1 are not specifically limited and may be variously modified as needed. FIGS. 3 and 5 illustrate an example in which each of the plurality of nanosheet stacks NSS includes four nanosheets including the first to fourth nanosheets N1, N2, N3, and N4; however, the present disclosure is not limited thereto. For example, the nanosheet stack NSS may include at least one nanosheet, and the number of nanosheets included in the nanosheet stack NSS is not specifically limited.

In implementations, each of the first to fourth nanosheets N1, N2, N3, and N4 may have a thickness selected in a range of about 4 nm to about 6 nm, without being limited thereto. Here, the thickness of each of the first to fourth nanosheets N1, N2, N3, and N4 refers to a size of each of the first to fourth nanosheets N1, N2, N3, and N4 in the vertical direction (Z direction). In implementations, the first to fourth nanosheets N1, N2, N3, and N4 may substantially have the same thickness in a vertical direction (Z direction). In other implementations, at least some of the first to fourth nanosheets N1, N2, N3, and N4 may have different thicknesses in the vertical direction (Z direction).

As illustrated in FIG. 3, the first to fourth nanosheets N1, N2, N3, and N4 included in one nanosheet stack NSS may have the same size or similar sizes in the first lateral direction (X direction). In other implementations, differently from that illustrated in FIG. 3, at least some of the first to fourth nanosheets N1, N2, N3, and N4 included in one nanosheet stack NSS may have different sizes in the first lateral direction (X direction).

As illustrated in FIGS. 3 and 5, each of the plurality of gate lines 160 may include a main gate portion 160M and a plurality of sub-gate portions 160S. The main gate portion 160M may cover an upper surface of the nanosheet stack NSS and extend lengthwise in the second lateral direction (Y direction). The plurality of sub-gate portions 160S may be integrally connected to the main gate portion 160M and respectively one-by-one arranged between the first to fourth nanosheets N1, N2, N3, and N4 and between the first nanosheet N1 and the fin top surface FF of the fin-type active region F1. In the vertical direction (Z direction), a thickness of each of the plurality of sub-gate portions 160S may be less than a thickness of the main gate portion 160M.

Each of the plurality of gate lines 160 may include a metal, a metal nitride, a metal carbide, or a combination thereof. The metal may be selected from molybdenum (Mo), ruthenium (Ru), copper (Cu), and tungsten (W). The metal nitride may be selected from titanium nitride (TiN), tantalum nitride (TaN), titanium aluminum nitride (TiAlN), or a combination thereof. The metal carbide may include titanium aluminum carbide (TiAlC). However, a material included in the plurality of gate lines 160 is not limited to the examples described above.

As illustrated in FIGS. 4 and 5, the device isolation film 112 may cover sidewalls of each of the plurality of fin-type active regions F1 in a second lateral direction (Y direction). As illustrated in FIG. 5, the device isolation film 112 may include a portion between the substrate 102 and the gate line 160 in the vertical direction (Z direction).

As illustrated in FIGS. 3 and 4, a plurality of recesses R1 may be formed in the fin-type active region F1. A lowermost surface of each of the plurality of recesses R1 may be at a lower vertical level than the fin top surface FF of the fin-type active region F1. A plurality of source/drain regions 130 may be respectively arranged inside the plurality of recesses R1. Each of the plurality of source/drain regions 130 may be arranged adjacent to at least one gate line 160 selected from the plurality of gate lines 160. On one fin-type active region F1, each of the plurality of source/drain regions 130 may be between two adjacent ones of the plurality of gate lines 160. Each of the plurality of source/drain regions 130 may have surfaces facing the first to fourth nanosheets N1, N2, N3, and N4 included in the nanosheet stack NSS adjacent thereto.

Each of the plurality of source/drain regions 130 may include an epitaxially grown semiconductor layer. In implementations, each of the plurality of source/drain regions 130 may include an epitaxially grown Si layer, an epitaxially grown SiC layer, or a plurality of epitaxially grown SiGe layers. When the source/drain region 130 constitutes an NMOS transistor, the source/drain region 130 may include a Si layer doped with an n-type dopant or a SiC layer doped with an n-type dopant. The n-type dopant may be selected from phosphorus (P), arsenic (As), and antimony (Sb). When the source/drain region 130 constitutes a PMOS transistor, the source/drain region 130 may include a SiGe film doped with a p-type dopant. The p-type dopant may be selected from boron (B) and gallium (Ga).

As illustrated in FIG. 3, both sidewalls of each of the plurality of gate lines 160 in the first lateral direction (X direction)) may be covered by insulating spacers 118. Each of a plurality of insulating spacers 118 included in the IC device 100 may extend lengthwise along with the gate line 160 in the second lateral direction (Y direction) on the nanosheet stack NSS and the device isolation film 112. The insulating spacers 118 may cover both sidewalls of the main gate portion 160M on upper surfaces of the plurality of nanosheet stacks NSS. The insulating spacer 118 may be spaced apart from the gate line 160 with the gate dielectric film 152 therebetween. The insulating spacer 118 may include silicon nitride, silicon oxide, silicon carbonitride (SiCN), silicon boron nitride (SiBN), silicon oxynitride (SiON), silicon oxycarbonitride (SiOCN), silicon boron carbonitride (SiBCN), silicon oxycarbide (SiOC), or a combination thereof. As used herein, each of the terms “SiCN,” “SiBN,” “SiON,” “SiOCN,” “SiBCN,” and “SiOC” refers to a material including elements included therein, without referring to a chemical formula representing a stoichiometric relationship.

A gate dielectric film 152 may be between the nanosheet stack NSS and the gate line 160. The gate dielectric film 152 may have a stack structure of an interface dielectric film and a high-k dielectric film. The interface dielectric film may include a low-k dielectric material film (e.g., a silicon oxide film, a silicon oxynitride film, or a combination thereof), which has a dielectric constant of about 9 or less. In implementations, the interface dielectric film may be omitted. The high-k dielectric film may include a material having a higher dielectric constant than a silicon oxide film. For example, the high-k dielectric film may have a dielectric constant of about 10 to 25. The high-k dielectric film may include hafnium oxide, without being limited thereto.

Both sidewalls of each of the plurality of sub-gate portions 160S included in the plurality of gate lines 160 may be spaced apart from the source/drain region 130 with the gate dielectric film 152 therebetween. The gate dielectric film 152 may include respective portions between the sub-gate portions 160S included in the gate line 160 and the first to fourth nanosheets N1, N2, N3, and N4, respective portions between the sub-gate portions 160S included in the gate line 160 and the source/drain region 130, and a portion between the fin top surface FF of the fin-type active region F1 and the sub-gate portion 160S, which is closest to the fin top surface FF of the fin-type active region F1, from among the plurality of sub-gate portions 160S included in the gate line 160.

As illustrated in FIGS. 3 and 4, a metal silicide film 172 may be formed on an upper surface of each of the plurality of source/drain regions 130. The metal silicide film 172 may include a metal, which includes titanium (Ti), tungsten (W), ruthenium (Ru), niobium (Nb), molybdenum (Mo), hafnium (Hf), nickel (Ni), cobalt (Co), platinum (Pt), ytterbium (Yb), terbium (Tb), dysprosium (Dy), erbium (Er), or palladium (Pd). For example, the metal silicide film 172 may include titanium silicide, without being limited thereto.

As illustrated in FIG. 4, an insulating liner 142 and an inter-gate dielectric film 144 may be sequentially arranged on the plurality of source/drain regions 130. In implementations, the insulating liner 142 may include silicon nitride (SiN), SiCN, SiBN, SiON, SiOCN, SiBCN, or a combination thereof, without being limited thereto. The inter-gate dielectric film 144 may include a silicon oxide film, without being limited thereto.

The device isolation film 112 may have an upper surface in contact with the insulating liner 142. A plurality of side insulating spacers 119 may be arranged on the device isolation film 112 on both sides of the source/drain region 130 in the second lateral direction (Y direction). Each of the plurality of side insulating spacers 119 may cover a sidewall of a partial region of the source/drain region 130, which is adjacent to the fin-type active region F1. The plurality of side insulating spacers 119 may be covered by the insulating liner 142. Each of the plurality of side insulating spacers 119 may include the same material as a constituent material of the insulating spacer 118. In other implementations, at least some of the plurality of side insulating spacers 119 may be omitted.

As illustrated in FIGS. 2, 3, and 4, a plurality of source/drain contacts 174 may be on the plurality of source/drain regions 130. Each of the plurality of source/drain contacts 174 may pass through an inter-gate dielectric structure including the inter-gate dielectric film 144 and the insulating liner 142 in the vertical direction (Z direction) and be electrically connected to at least one source/drain region 130 selected from the plurality of source/drain regions 130. A portion of a lower surface of each of the plurality of source/drain contacts 174 may be in contact with the metal silicide film 172 formed on the source/drain region 130. The metal silicide film 172 may be between the source/drain region 130 and the source/drain contact 174.

Each of the plurality of source/drain contacts 174 may be electrically connectable to the at least one source/drain region 130 through the metal silicide film 172. For example, the plurality of source/drain contacts 174 may be electrically connectable to a pair of source/drain regions 130 located on a pair of adjacent fin-type active regions F1 as illustrated in FIG. 4. However, the configuration illustrated in FIG. 4 is only an implementation, and some of the source/drain contacts 174 may be configured to be electrically connectable to one source/drain region 130, and some others of the source/drain contacts 174 may be configured to be electrically connectable to three source/drain regions 130.

Each of the plurality of source/drain contacts 174 may be spaced apart from the main gate portion 160M of the gate line 160 with the insulating spacer 118 therebetween in the first lateral direction (X direction). The plurality of insulating spacers 118 may be respectively between the plurality of gate lines 160 and the plurality of source/drain contacts 174.

As illustrated in FIGS. 2 and 4, a plurality of contact isolation insulating structures CX may be respectively arranged in a line between the plurality of gate lines 160 in a second lateral direction (Y direction). Each of the plurality of contact isolation insulating structures CX may be between two source/drain contacts 174, which are adjacent to each other in the second lateral direction (Y direction), and may electrically isolate the two adjacent source/drain contacts 174 from each other. Each of the plurality of contact isolation insulating structures CX located between a pair of adjacent ones of the plurality of gate lines 160 may be between a pair of source/drain contacts 174, which are adjacent to each other in the second lateral direction (Y direction), from among the plurality of source/drain contacts 174, and may be arranged in a line in an imaginary straight line, which is in the second lateral direction (Y direction). A length of each of the plurality of source/drain contacts 174 in the second lateral direction (Y direction) may be defined by the contact isolation insulating structure CX that is adjacent thereto. In implementations, each of the plurality of contact isolation insulating structures CX may include a silicon oxide film, a silicon oxynitride film, a silicon oxycarbide film, or a combination thereof. In other implementations, at least some of the plurality of contact isolation insulating structures CX may include air gaps. As used herein, the term “air gap” may refer to space including the atmosphere or other gases that may be during a manufacturing process.

As illustrated in FIG. 7, each of the plurality of source/drain contacts 174 may have a first upper surface TS1 extending at a first vertical level LV1. As used herein, the term “vertical level” refers to a distance in the vertical direction (Z direction) from a reference vertical level LV0, which is a vertical level of an uppermost surface of the nanosheet stack NSS. A source/drain via contact VA may be arranged on the source/drain contact 174. The source/drain via contact VA may have a structure that protrudes from the first upper surface TS1 of the source/drain contact 174 in the vertical direction (Z direction) and is integrally connected to the source/drain contact 174. Here, the source/drain via contact VA can be considered to be integrally connected to the source/drain contact 174 when the source/drain via contact VA and the source/drain contact 174 are formed during the same deposition process, include the same material, and/or have an interface that is indistinguishable. The source/drain contact 174 may include the same material as the source/drain via contact VA. In implementations, each of the source/drain contact 174 and the source/drain via contact VA may include a metal plug and a conductive barrier film surrounding the metal plug. The metal plug may include molybdenum (Mo), tungsten (W), cobalt (Co), ruthenium (Ru), manganese (Mn), titanium (Ti), tantalum (Ta), aluminum (Al), copper (Cu), a combination thereof, or an alloy thereof, without being limited thereto. The conductive barrier film may include a metal or a metal nitride. For example, the conductive barrier film may include titanium (Ti), tantalum (Ta), tungsten (W), titanium nitride (TiN), tantalum (TaN), tungsten nitride (WN), tungsten carbon nitride (WCN), titanium silicon nitride (TiSiN), tantalum silicon nitride (TaSiN), tungsten silicon nitride (WSiN), or a combination thereof, without being limited thereto. In implementations, the conductive barrier film may be omitted in each of the source/drain contact 174 and the source/drain via contact VA. A source/drain contact in the present disclosure can refer to either a source contact for a source region or a drain contact for a drain region. Similarly, a source/drain via contact in the present disclosure can refer to either a source via contact for a source region or a drain via contact for a drain region.

A source/drain contact extension 184A may be arranged on the source/drain contact 174 at a position spaced apart from the source/drain via contact VA in the second lateral direction (Y direction). The source/drain contact extension 184A may be in contact with the first upper surface TS1 of the source/drain contact 174 and have a second upper surface TS2 at a second vertical level LV2 that is higher than the first vertical level LV1 of the first upper surface TS1. The second upper surface TS2 of the source/drain contact extension 184A may be arranged farther from the source/drain region 130 than the first upper surface TS1 of the source/drain contact 174. The source/drain contact extension 184A may be spaced apart from the metal silicide film 172 in the vertical direction (Z direction) with the source/drain contact 174 therebetween. The source/drain contact 174 and the source/drain contact extension 184A may constitute a source/drain contact structure CA.

As illustrated in FIGS. 3 and 6, the source/drain contact structure CA may have a variable width in the vertical direction (Z direction). That is, in the first lateral direction (X direction), the source/drain contact 174 of the source/drain contact structure CA may have a first width CW1, and the source/drain contact extension 184A of the source/drain contact structure CA may have a second width CW2 that is less than the first width CW1. Accordingly, in the source/drain contact structure CA, there may be a step between a sidewall of the source/drain contact 174 and a sidewall of the source/drain contact extension 184A.

The source/drain contact extension 184A may include a metal or a conductive metal nitride. For example, the source/drain contact extension 184A may include molybdenum (Mo), tungsten (W), cobalt (Co), ruthenium (Ru), manganese (Mn), titanium (Ti), tantalum (Ta), aluminum (Al), copper (Cu), a combination thereof, or an alloy thereof, without being limited thereto. In implementations, a constituent material of the source/drain contact extension 184A may be the same as a constituent material of the source/drain contact 174. For example, each of the source/drain contact 174 and the source/drain contact extension 184A may include molybdenum (Mo), without being limited thereto. In implementations, the source/drain contact 174, the source/drain via contact VA, and the source/drain contact extension 184A may include the same metal. For example, each of the source/drain contact 174, the source/drain via contact VA, and the source/drain contact extension 184A may include molybdenum (Mo), without being limited thereto.

As illustrated in FIGS. 3 and 5, each of the plurality of gate lines 160 may have a third upper surface TS3 extending at a third vertical level LV3. The third vertical level LV3 may be a vertical level that is identical or similar to the first vertical level LV1. A gate contact CB may be arranged on the gate line 160. The gate contact CB may have a structure that protrudes from the third upper surface TS3 of the gate line 160 in the vertical direction (Z direction) and is integrally connected to the gate line 160. Here, the gate contact CB can be considered to be integrally connected to the gate line 160 when the gate contact CB and the gate line 160 are formed during the same deposition process, include the same material, and/or have an interface that is indistinguishable. The gate contact CB may include the same material as at least a portion of the gate line 160. In implementations, the gate contact CB may include tungsten (W), without being limited thereto.

A gate extension 184B may be arranged on the gate line 160 at a position spaced apart from the gate contact CB in the second lateral direction (Y direction). The gate extension 184B may have a fourth upper surface TS4, which is in contact with the third upper surface TS3 of the gate line 160 and is at a fourth vertical level LV4 that is higher than the third vertical level LV3 of the third upper surface TS3. The gate line 160 and the gate extension 184B may constitute a gate structure GST.

As illustrated in FIGS. 3 and 6, the gate structure GST may have a variable width in the vertical direction (Z direction). That is, in the first lateral direction (X direction), the gate line 160 of the gate structure GST may have a first width GW1, and the gate extension 184B of the gate structure GST may have a second width GW2 that is less than the first width GW1. Accordingly, in the gate structure GST, there may be a step between the sidewall of the gate line 160 and a sidewall of the gate extension 184B.

A constituent material of the gate extension 184B may be the same as a constituent material of the source/drain contact extension 184A. For example, the gate extension 184B and the source/drain contact extension 184A may include molybdenum (Mo), without being limited thereto. The constituent material of the gate extension 184B may be different from a constituent material of a portion of the third upper surface TS3 of the gate line 160, which is in contact with the gate extension 184B. For example, a portion of the third upper surface TS3 of the gate line 160, which is in contact with the gate extension 184B, may include tungsten (W), and the gate extension 184B may include molybdenum (Mo), without being limited thereto.

As illustrated in FIGS. 3 to 7, a first insulating barrier wall 180A may be between the source/drain via contact VA and the source/drain contact extension 184A, and a second insulating barrier wall 180B may be between the gate contact CB and the gate extension 184B. The first insulating barrier wall 180A may be in contact with the first upper surface TS1 of the source/drain contact 174, and the second insulating barrier wall 180B may be in contact with the third upper surface TS3 of the gate line 160.

In a plan view (X-Y plane), the first insulating barrier wall 180A may cover sidewalls of the source/drain contact extension 184A to surround the source/drain contact extension 184A. The first insulating barrier wall 180A may cover both sidewalls of the source/drain contact extension 184A in the first lateral direction (X direction) and both sidewalls of the source/drain contact extension 184A in the second lateral direction (Y direction), from among sidewalls of the source/drain contact extension 184A. The first insulating barrier wall 180A may include a portion (e.g., a first portion) located between the source/drain via contact VA and the source/drain contact extension 184A in the second lateral direction (Y direction) and a portion (e.g., a second portion) located between the insulating spacer 118 and the source/drain contact extension 184A in the first lateral direction (X direction).

In a plan view (X-Y plane), the second insulating barrier wall 180B may cover sidewalls of the gate extension 184B to surround the gate extension 184B. The second insulating barrier wall 180B may cover both sidewalls of the gate extension 184B in the first lateral direction (X direction) and both sidewalls of the gate extension 184B in the second lateral direction (Y direction), from among sidewalls of the gate extension 184B. The second insulating barrier wall 180B may include a portion (e.g., a first portion) located between the gate contact CB and the gate extension 184B in the second lateral direction (Y direction) and a portion (e.g., a second portion) located between the insulating spacer 118 and the gate extension 184B in the first lateral direction (X direction).

As illustrated in FIGS. 3 to 7, a first metal-containing conductive liner 176A may be arranged on the source/drain via contact VA, and a second metal-containing conductive liner 176B may be arranged on the gate contact CB. A lower surface of the first metal-containing conductive liner 176A may be in contact with an upper surface of the source/drain via contact VA. A lower surface of the second metal-containing conductive liner 176B may be in contact with an upper surface of the gate contact CB.

The first metal-containing conductive liner 176A and the second metal-containing conductive liner 176B may each include a metal, a conductive metal nitride, or a combination thereof. The first metal-containing conductive liner 176A may include the same metal element as the second metal-containing conductive liner 176B. The first metal-containing conductive liner 176A may include the same material as the second metal-containing conductive liner 176B. In implementations, each of the first metal-containing conductive liner 176A and the second metal-containing conductive liner 176B may have a single film structure including a conductive metal nitride film or a multilayered film structure including a combination of a conductive metal nitride film and a metal film. In implementations, the first metal-containing conductive liner 176A and the second metal-containing conductive liner 176B may include the same material, which is selected from Ti, TiN, Ta, TaN, Mo, W, Ru, Nb, Ni, Co, Pt, Yb, Tb, Dy, Er, Pd, and a combination thereof. For example, the first metal-containing conductive liner 176A and the second metal-containing conductive liner 176B may each include TiN, without being limited thereto.

In implementations, the source/drain via contact VA may include a first metal, and the first metal-containing conductive liner 176A may include a second metal that is different from the first metal. For example, the source/drain via contact VA may include molybdenum (Mo), and the first metal-containing conductive liner 176A may include titanium (Ti), without being limited thereto.

As illustrated in FIGS. 3 and 6, an uppermost surface of the insulating spacer 118 may be at a fifth vertical level LV5, which is higher than a second vertical level LV2 of the second upper surface TS2 of the source/drain contact extension 184A and higher than the fourth vertical level LV4 of the fourth upper surface TS4 of the gate extension 184B. As illustrated in FIG. 7, an uppermost surface of the contact isolation insulating structure CX may be at a sixth vertical level LV6, which is at the second vertical level LV2 of the second upper surface TS2 of the source/drain contact extension 184A and higher than the fourth vertical level LV4 of the fourth upper surface TS4 of the gate extension 184B. The fifth vertical level LV5 may be identical or similar to the sixth vertical level LV6.

The insulating spacer 118, the source/drain contact extension 184A, the gate extension 184B, the first insulating barrier wall 180A, and the second insulating barrier wall 180B may be covered by a capping insulating film 188. The capping insulating film 188 may include a silicon oxide film.

A wiring structure MST may be arranged on the capping insulating film 188 and a plurality of first and second metal-containing conductive liners 176A and 176B. The wiring structure MST may include a plurality of wiring layers. From among the plurality of wiring layers included in the wiring structure MST, wiring layers that are closest to the substrate 102 may be a plurality of first wiring layers 190 that are respectively in contact with the plurality of first and second metal-containing conductive liners 176A and 176B. The plurality of first wiring layers 190 may each include a vertical extension and a horizontal extension. The vertical extension may pass through a portion of the capping insulating film 188 in the vertical direction (Z direction) and be in contact with one of the plurality of first and second metal-containing conductive liners 176A and 176B. The horizontal extension may cover an upper surface of the capping insulating film 188. The vertical extension may be integrally connected to the horizontal extension. The plurality of first wiring layers 190 may include molybdenum (Mo), copper (Cu), tungsten (W), cobalt (Co), ruthenium (Ru), manganese (Mn), titanium (Ti), tantalum (Ta), aluminum (Al), a combination thereof, or an alloy thereof, without being limited thereto.

The IC device 100 described with reference to FIGS. 2 to 7 may include a source/drain contact structure CA including the source/drain contact 174 and the source/drain contact extension 184A. The source/drain contact extension 184A may supplement the thickness of a relatively thin portion of the source/drain contact 174 so that defects may be prevented from occurring due to a portion of the source/drain contact 174, which has a relatively small thickness in the vertical direction (Z direction), being disconnected or excessively thinned out. Accordingly, the reliability of the IC device 100 may improve. Furthermore, the first insulating barrier wall 180A covering sidewalls of the source/drain contact extension 184A and the second insulating barrier wall 180B covering sidewalls of the gate extension 184B may block the possibility of undesired short-circuits between the source/drain contact extension 184A and another conductive member (e.g., the gate line 160) adjacent thereto during the formation of the source/drain contact extension 184A. Therefore, a sufficient insulation distance may be ensured between the source/drain contact extension 184A and another conductive member (e.g., the gate line 160) adjacent thereto.

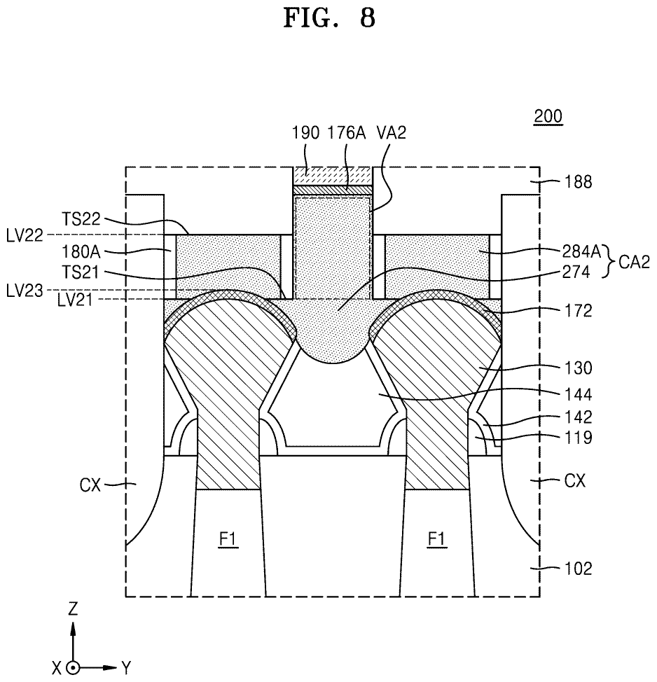

FIG. 8 is a cross-sectional view of an IC device 200 according to implementations. FIG. 8 illustrates an enlarged cross-sectional configuration of a region corresponding to portion “EX2” of FIG. 4 in the IC device 200. In FIG. 8, the same reference numerals are used to denote the same elements as in FIGS. 2 to 7, and thus, any redundant description thereof is omitted. Components of the IC device 200 described with reference to FIG. 8 may constitute some of the plurality of cells LC illustrated in FIG. 1.

Referring to FIG. 8, the IC device 200 may substantially have the same configuration as the IC device 100 described with reference to FIGS. 2 to 7. However, the IC device 200 illustrated in FIG. 8 may include a source/drain contact 274 and a source/drain contact structure CA2 including a source/drain contact extension 284A. A source/drain via contact VA2 may be arranged on the source/drain contact 274. The source/drain via contact VA2 may have a structure that protrudes from a first upper surface TS21 of the source/drain contact 274 in a vertical direction (Z direction) and is integrally connected to the source/drain contact 274. The source/drain contact 274 may include the same material as the source/drain via contact VA2. Detailed configurations the source/drain contact 274, the source/drain via contact VA2, and the source/drain contact extension 284A may substantially be the same as those of the source/drain contact 174, the source/drain via contact VA, and the source/drain contact extension 184A, which have been described with reference to FIGS. 2, 3, 4, 6, and 7. However, a first vertical level LV21 of the first upper surface TS21 of the source/drain contact 274 may be lower than a vertical level LV23 of an uppermost surface of a metal silicide film 172. The vertical level LV23 of the uppermost surface of the metal silicide film 172 may be higher than the first vertical level LV21 of the first upper surface TS21 of the source/drain contact 274 and be lower than a second vertical level LV22 of a second upper surface TS22 of the source/drain contact extension 284A. Thus, the source/drain contact extension 284A may include a portion in contact with the metal silicide film 172.

During the process of manufacturing the IC device 200 illustrated in FIG. 8, even when the metal silicide film 172 covering the source/drain region 130 is exposed over the first upper surface TS21 of the source/drain contact 274 due to various causes after the formation of the source/drain contact 274, the source/drain contact extension 284A formed in a subsequent process may cover the metal silicide film 172 exposed over the first upper surface TS21 of the source/drain contact 274. Thus, the source/drain contact extension 284A may supplement the thickness of a disconnected portion of the source/drain contact 174 so that defects may be prevented from occurring due to the source/drain contact 274 being disconnected by the source/drain region 130 and/or the metal silicide film 172. Accordingly, the reliability of the IC device 200 may improve.

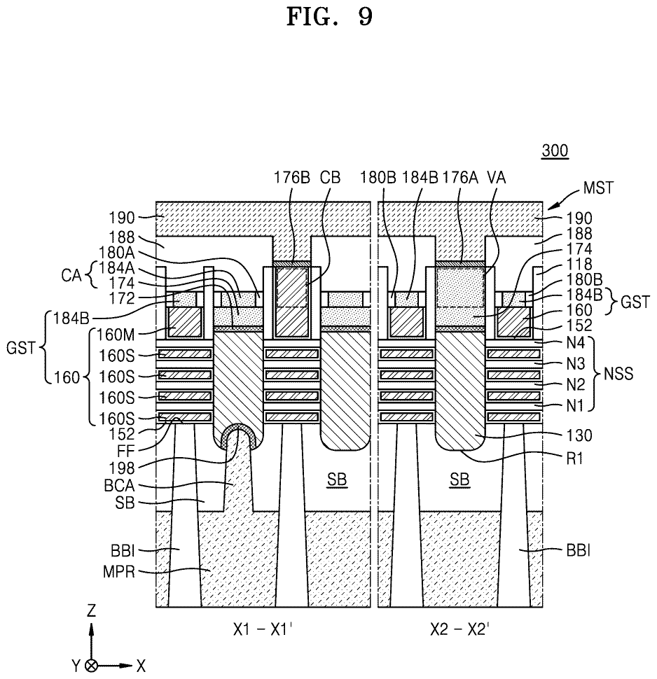

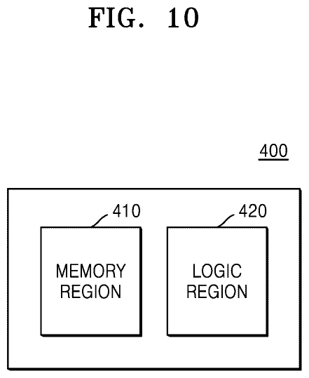

FIG. 9 is a cross-sectional view of an IC device 300 according to implementations. FIG. 9 illustrates components of regions corresponding respectively to a cross-section taken along line X1-X1′ of FIG. 2 and a cross-section taken along line X2-X2′ of FIG. 2 in the IC device 300. In FIG. 9, the same reference numerals are used to denote the same elements as in FIGS. 2 to 7, and thus, any redundant description thereof is omitted. Components of the IC device 300 described with reference to FIG. 9 may constitute some of the plurality of cells LC illustrated in FIG. 1.

Referring to FIG. 9, the IC device 300 may substantially have the same configuration as the IC device 100 described with reference to FIGS. 2 to 7. However, the IC device 300 may not include a substrate (refer to 102 in FIGS. 3 to 5) but may include a backside source/drain contact BCA and a backside power rail MPR connected to the backside source/drain contact BCA.

The backside source/drain contact BCA may be configured to be connected to a backside surface of a selected one of a plurality of source/drain regions 130. The backside source/drain contact BCA may pass through a lower portion of a corresponding one of the source/drain regions 130 in a vertical direction (Z direction) from a back side of the source/drain region 130.

A backside metal silicide film 198 may be between the backside source/drain contact BCA and the source/drain region 130 connected to the backside source/drain contact BCA, from among the plurality of source/drain regions 130. The backside source/drain contact BCA may be configured to be connected to a corresponding one of the source/drain regions 130 through the backside metal silicide film 198. A constituent material of the backside metal silicide film 198 may substantially be the same as a constituent material of the metal silicide film 172 described above with reference to FIGS. 3 and 4.

FIG. 9 illustrates a configuration in which a source/drain contact structure CA is connected to the frontside surface of the source/drain region 130 to which the backside source/drain contact BCA is connected; however, the present disclosure is not limited thereto. Differently from that illustrated in FIG. 9, the source/drain contact structure CA may not be connected to the source/drain region 130 to which the backside source/drain contact BCA is connected. As used herein, the backside surface and the frontside surface of the source/drain region 130 may refer to opposite surfaces of the source/drain regions 130 in a vertical direction (Z direction). The backside surface of the source/drain region 130 may be a surface of the source/drain region 130, which faces the backside power rail MPR.

The IC device 300 may include a plurality of backside bulk insulating films BBI, which are arranged in a line in a first lateral direction (X direction) and each extend lengthwise in a second lateral direction (Y direction). A plurality of backside power rails MPR may be separated from each other by the plurality of backside bulk insulating films BBI in the first lateral direction (X direction). The plurality of backside power rails MPR may be respectively arranged one-by-one between the plurality of backside bulk insulating films BBI in the first lateral direction (X direction). The backside source/drain contact BCA may be integrally connected to a selected one of the plurality of backside power rails MPR. A plurality of nanosheet stacks NSS may be spaced apart from the plurality of backside bulk insulating films BBI in the vertical direction (Z direction). Each of the plurality of backside bulk insulating films BBI may extend lengthwise in the vertical direction (Z direction) at a position overlapping a selected one of a plurality of gate lines 160 in the vertical direction (Z direction).

Each of the plurality of backside bulk insulating films BBI may be in contact with a pair of adjacent backside power rails MPR, which are selected from the plurality of backside power rails MPR. Each of the plurality of backside bulk insulating films BBI may extend lengthwise in the vertical direction (Z direction) from a space between a pair of adjacent backside power rails MPR toward a selected one of the plurality of gate lines 160. In implementations, each of the plurality of backside bulk insulating films BBI may include a nitrogen-containing insulating film. For example, each of the plurality of backside bulk insulating films BBI may include silicon nitride (SiN), silicon carbonitride (SiCN), silicon oxycarbonitride (SiOCN), or a combination thereof, without being limited thereto.

The backside source/drain contact BCA may extend lengthwise in the vertical direction between a pair of adjacent ones of the plurality of backside bulk insulating films BBI. From among the plurality of backside power rails MPR, the backside power rail MPR that is integrally connected to the backside source/drain contact BCA may be spaced apart from the source/drain region 130 in the vertical direction (Z direction) with the backside source/drain contact BCA therebetween.

In implementations, the backside source/drain contact BCA and the backside power rail MPR may be simultaneously formed using a single process and may include the same material. In other implementations, the backside source/drain contact BCA and the backside power rail MPR may be formed using separate processes, and an interface may be present between the backside source/drain contact BCA and the backside power rail MPR. In implementations, the backside source/drain contact BCA and the backside power rail MPR may include a single metal. In other implementations, a source/drain contact 174 may include a metal plug and a conductive barrier film surrounding the metal plug. The metal plug may include molybdenum (Mo), tungsten (W), cobalt (Co), ruthenium (Ru), manganese (Mn), titanium (Ti), tantalum (Ta), aluminum (Al), copper (Cu), a combination thereof, or an alloy thereof, without being limited thereto. The conductive barrier film may include a metal or a conductive metal nitride. For example, the conductive barrier film may include Ti, Ta, W, TiN, TaN, WN, WCN, TiSiN, TaSiN, WSiN, or a combination thereof, without being limited thereto.

The IC device 300 may include a plurality of semiconductor blocks SB. Some of the semiconductor blocks SB may cover a side surface of the backside source/drain contact BCA in the first lateral direction (X direction). Some others of the semiconductor blocks SB may be in contact with the backside surface of the source/drain region 130 to which the source/drain contact 174 is connected. Each of the plurality of semiconductor blocks SB may include silicon (Si).

At least some of the semiconductor blocks SB may cover a sidewall of the backside bulk insulating film BBI in the first lateral direction (X direction). The plurality of semiconductor blocks SB may be in contact with a gate dielectric film 152 covering a lowermost surface of the gate line 160. As used herein, the lowermost surface of the gate line 160 may refer to a surface of the gate line 160, which is closest to the backside power rail MPR.

The IC device 300 described with reference to FIG. 9 may have the same effects as the IC device 100 described with reference to FIGS. 2 to 7.

FIG. 10 is a block diagram of an IC device 400 according to implementations.

Referring to FIG. 10, the IC device 400 may include a memory region 410 and a logic region 420. At least one of the memory region 410 and the logic region 420 may include at least one of configurations of the IC devices 100, 200, and 300, which have been described with reference to FIGS. 2 to 9.

The memory region 410 may include at least one of static random access memory (SRAM), dynamic RAM (DRAM), magnetic RAM (MRAM), resistive RAM (RRAM), and phase-change RAM (PRAM). For example, the memory region 410 may include SRAM. The logic region 420 may include standard cells (e.g., a counter and a buffer) configured to perform desired logical functions. The standard cells may include various types of logic cells including a plurality of circuit elements, such as transistors and registers. The logic cell may include, for example, an AND, a NAND, an OR, a NOR, an exclusive OR (XOR), an exclusive NOR (XNOR), an inverter (INV), an adder (ADD), a buffer (BUF), a delay (DLY), a filter (FIL), a multiplexer (MXT/MXIT), an OR/AND/INVERTER (OAI), an AND/OR (AO), an AND/OR/INVERTER (AOI), a D-flip-flop, a reset flip-flop, a master-slave flip-flop, and/or a latch.

Next, a method of manufacturing an IC device, according to implementations, is described in detail.

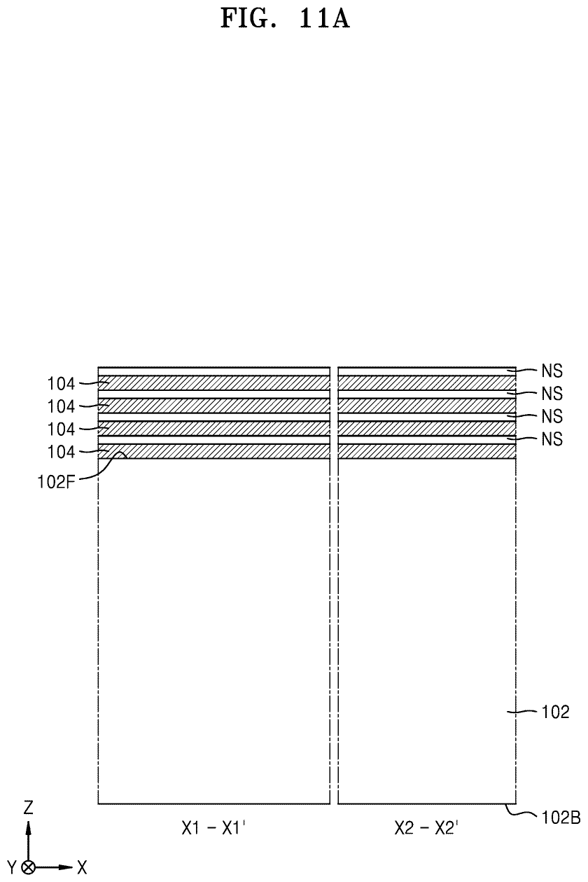

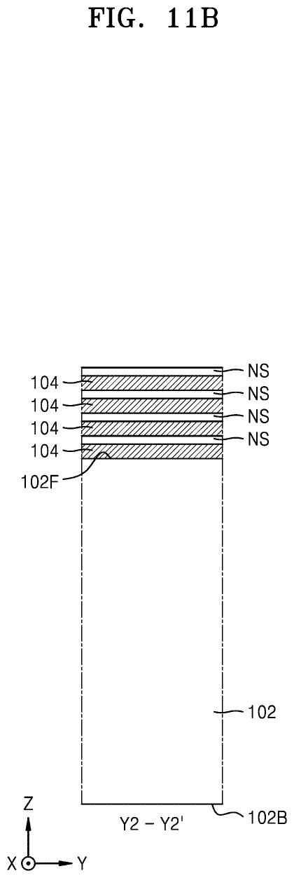

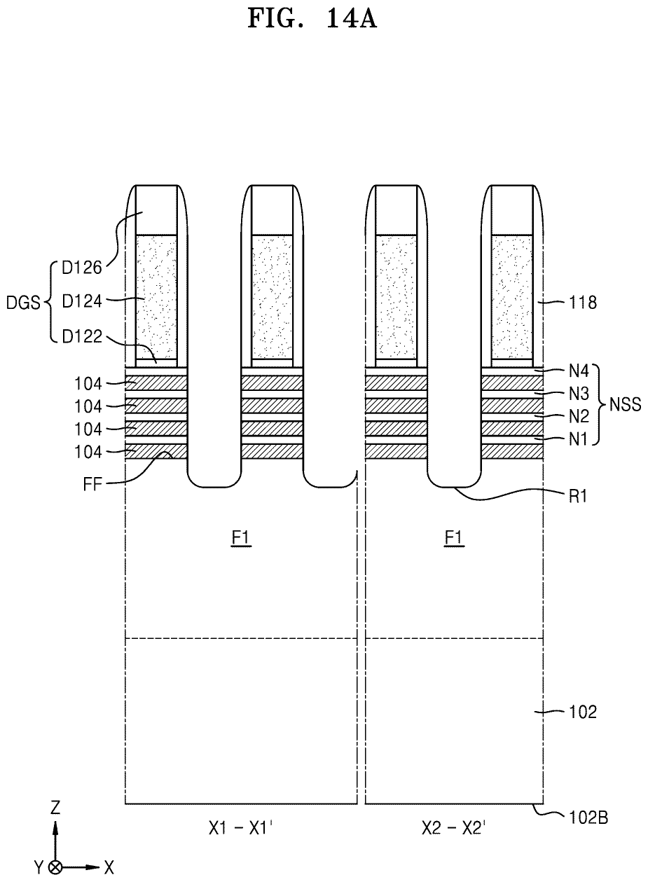

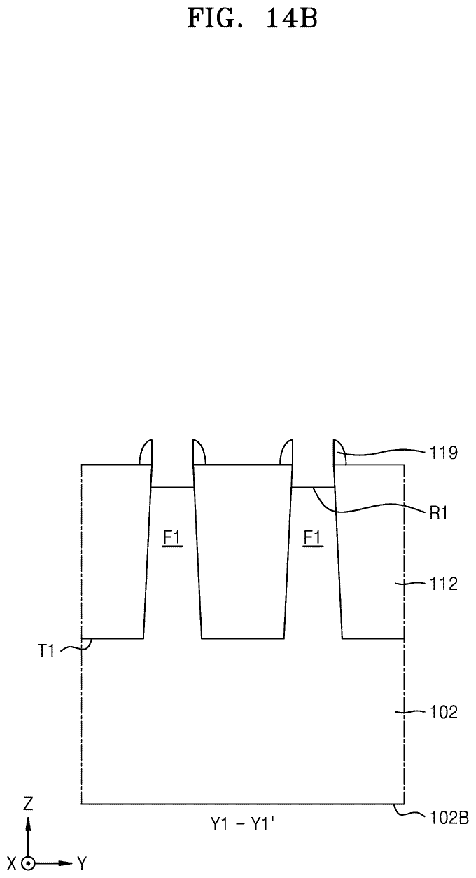

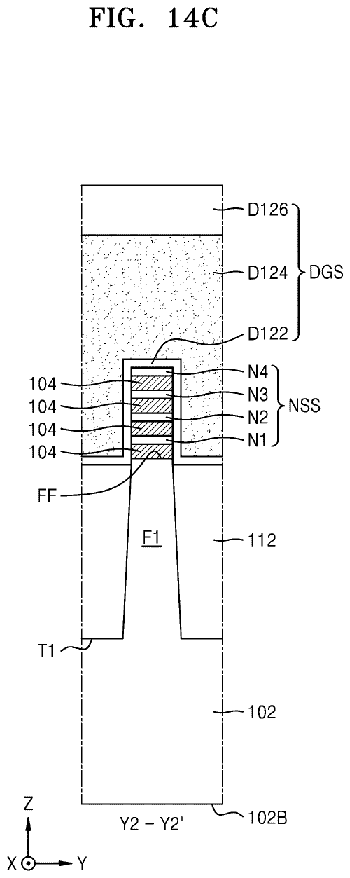

FIGS. 11A to 31C are cross-sectional views illustrating a process sequence of a method of manufacturing an IC device, according to implementations. More specifically, FIGS. 11A, 12A, 13A, 14A, 15A, 16A, 17A, 18A, 20A, 21A, 22A, 23A, 24A, 25A, 26A, 27A, 28A, 29A, 30A, and 31A are cross-sectional views of examples of cross-sectional structures of a portion corresponding to a cross-section taken along line X1-X1′ of FIG. 2 and a cross-section taken along line X2-X2′ of FIG. 2, according to the process sequence. FIGS. 14B, 15B, 19, 20B, 21B, 22B, 23B, 24B, 25B, 26B, 27B, 28B, 29B, 30B, and 31B are cross-sectional views of examples of cross-sectional structures of a portion corresponding to a cross-section taken along line Y1-Y1′ of FIG. 2, according to the process sequence. FIGS. 11B, 12B, 13B, 14C, 15C, 16B, 17B, 18B, 23C, 24C, 25C, 26C, 27C, 28C, 29C, 30C, and 31C are cross-sectional views of examples of cross-sectional structures of a portion corresponding to a cross-section taken along line Y2-Y2′ of FIG. 2, according to the process sequence. An example of a method of manufacturing the IC device 100 illustrated in FIGS. 2 to 7 is described with reference to FIGS. 11A to 31C. In FIGS. 11A to 31C, the same reference numerals are used to denote the same elements as in FIGS. 2 to 7, and thus, any redundant description thereof is omitted.

Referring to FIGS. 11A and 11B, a substrate 102 having a frontside surface 102F and a backside surface 102B, which are opposite to each other, may be prepared. A plurality of sacrificial semiconductor layers 104 and a plurality of nanosheet semiconductor layers NS may be alternately stacked one-by-one on the frontside surface 102F of the substrate 102 to form a stack structure.

In the stack structure, the plurality of sacrificial semiconductor layers 104 and the plurality of nanosheet semiconductor layers NS may include semiconductor materials having different etch selectivities from each other. In implementations, the plurality of nanosheet semiconductor layers NS may include a Si layer, and the plurality of sacrificial semiconductor layers 104 may include a SiGe film. The SiGe film included in the sacrificial semiconductor layer 104 may have a constant Ge content, which is selected in a range of about 5 at % to about 50 at %, for example, about 10 at % to about 40 at %. In implementations, the plurality of sacrificial semiconductor layers 104 may each include a SiGe film and have the same Ge content.

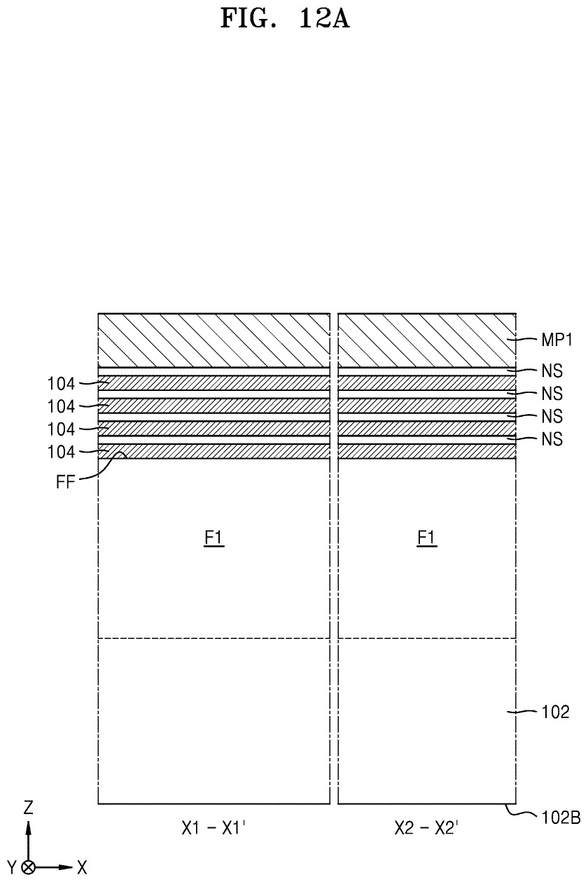

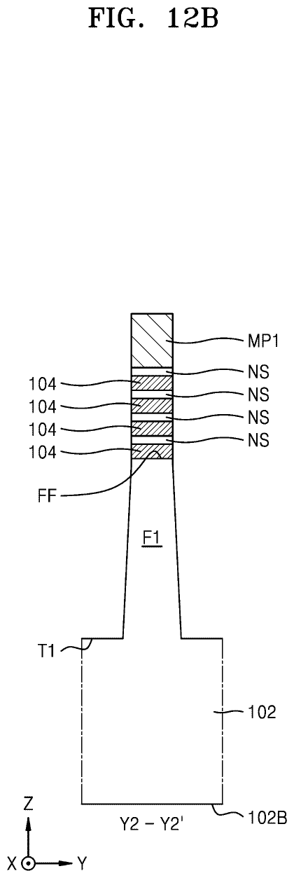

Referring to FIGS. 12A and 12B, a mask pattern MP1 having openings exposing an upper surface of the stack structure may be formed on the resultant structure of FIGS. 11A and 11B. The mask pattern MP1 may include a stack structure of a silicon oxide film pattern and a silicon oxide film pattern. The mask pattern MP1 may include portions extending parallel to each other in a first lateral direction (X direction) on the substrate 102.

A portion of each of the plurality of sacrificial semiconductor layers 104, the plurality of nanosheet semiconductor layers NS, and the substrate 102 may be etched using the mask pattern MP1 as an etch mask, and thus, a plurality of fin-type active regions F1 may be formed on the substrate 102. A plurality of trenches T1 may be defined in the substrate 102 by the plurality of fin-type active regions F1. A portion of each of the plurality of sacrificial semiconductor layers 104 and the plurality of nanosheet semiconductor layers NS may remain on a fin top surface FF of each of the plurality of fin-type active regions F1.

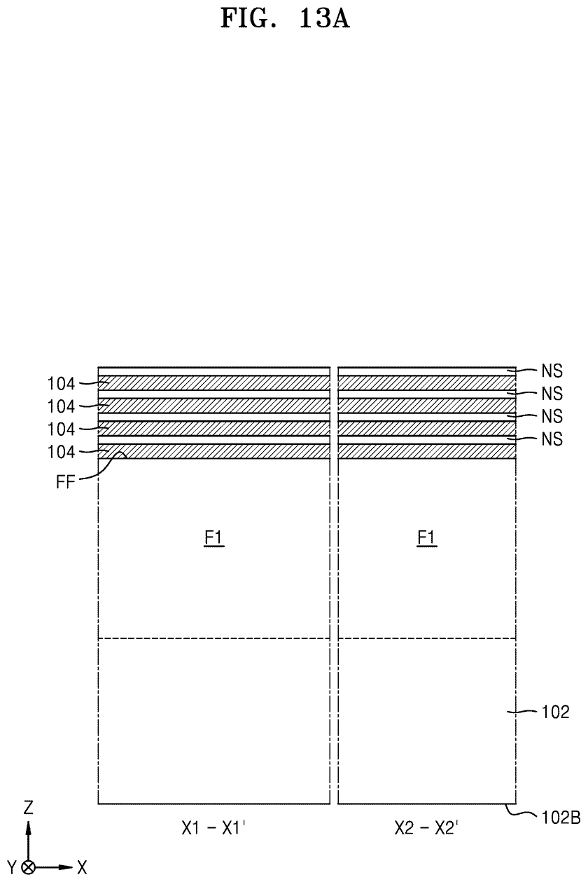

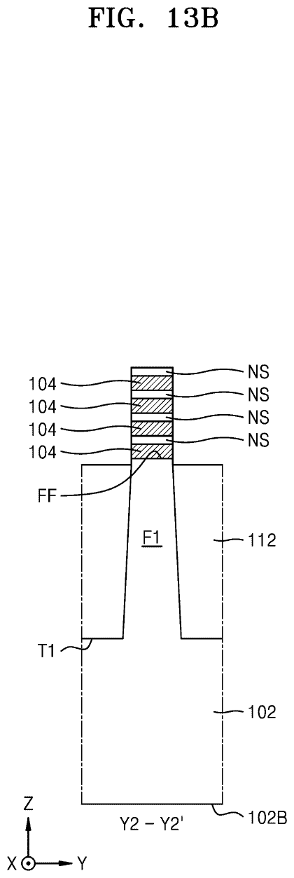

Referring to FIGS. 13A and 13B, a device isolation film 112 may be formed on the resultant structure of FIGS. 12A and 12B. The device isolation film 112 may be formed to fill the plurality of trenches T1 and cover sidewalls of each of the plurality of fin-type active regions F1.

The formation of the device isolation film 112 may include forming an insulating film having such a sufficient thickness as to fill the plurality of trench regions T1 on the resultant structure of FIGS. 12A and 12B, planarizing the obtained resultant structure to expose an upper surface of the mask pattern MP1, removing the exposed mask pattern MP1, and performing a recess process of removing a portion of the insulating film. Thus, the device isolation film 112 including the remaining portion of the insulating film may be formed. After the device isolation film 112 is formed, a stack structure including the plurality of sacrificial semiconductor layers 104 and the plurality of nanosheet semiconductor layers NS, which remain on the substrate 102, may protrude over an upper surface of the device isolation film 112, and an upper surface of an uppermost one of the plurality of nanosheet semiconductor layers NS may be exposed.

Referring to FIGS. 14A, 14B, and 14C, a plurality of dummy gate structures DGS may be formed on the resultant structure of FIGS. 13A and 13B. Each of the plurality of dummy gate structures DGS may be formed to extend lengthwise in a second lateral direction (Y direction). Each of the plurality of dummy gate structures DGS may include a dummy oxide film D122, a dummy gate layer D124, and a capping layer D126, which are sequentially stacked on the stack structure including the plurality of sacrificial semiconductor layers 104 and the plurality of nanosheet semiconductor layers NS. In implementations, the dummy gate layer D124 may include polysilicon, and the capping layer D126 may include a silicon oxide film.

As illustrated in FIG. 14A, a plurality of insulating spacers 118 may be respectively formed on both sidewalls of the plurality of dummy gate structures DGS. A portion of each of the plurality of sacrificial semiconductor layers 104 and the plurality of nanosheet semiconductor layers NS and a portion of the fin-type active region F1 may be etched by using the plurality of dummy gate structures DGS and the plurality of insulating spacers 118 as etch masks. Thus, the plurality of nanosheet semiconductor layers NS may be divided into a plurality of nanosheet stacks NSS including the first to fourth nanosheets N1, N2, N3, and N4, and a plurality of recesses R1 may be formed in the fin-type active region F1. Widths of the first to fourth nanosheets N1, N2, N3, and N4 in the first lateral direction (X direction) may be defined by the plurality of recesses R1.

To form the plurality of recesses R1, an etching process may be performed by using a dry etching process, a wet etching process, or a combination thereof. During the formation of the plurality of insulating spacers 118 and the plurality of recesses R1, as illustrated in FIG. 14B, a plurality of side insulating spacers 119 may be formed adjacent to the plurality of recesses R1 on the device isolation film 112 on both sides of each of the fin-type active region F1 in the second lateral direction (Y direction).

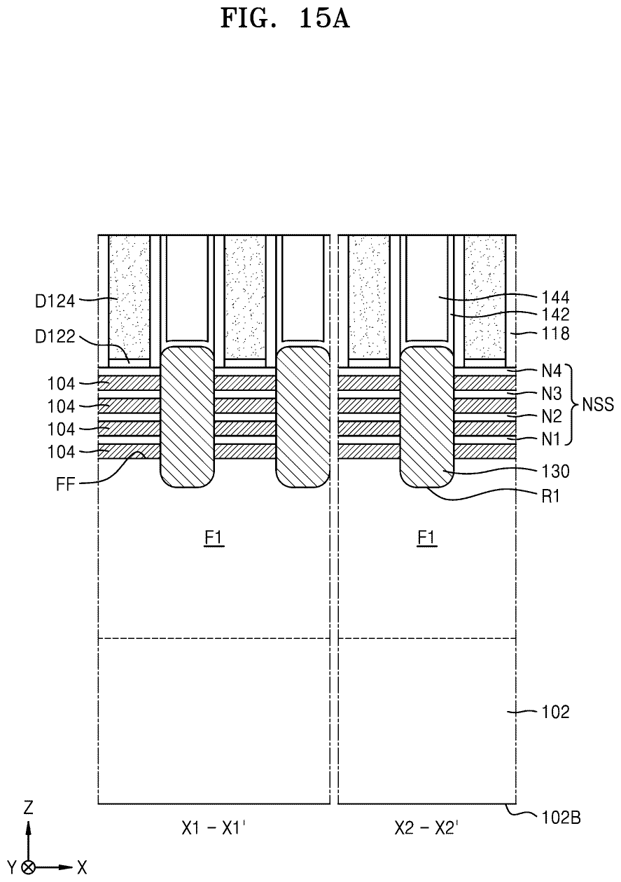

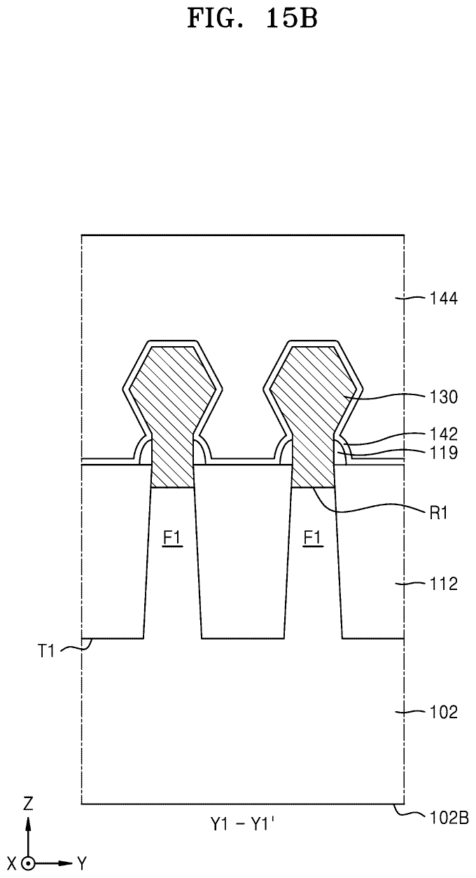

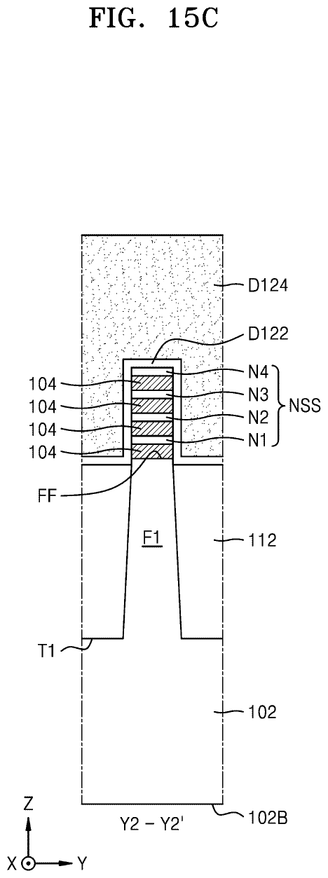

Referring to FIGS. 15A, 15B, and 15C, a plurality of source/drain regions 130 filling the plurality of recesses R1 may be formed in the resultant structure of FIGS. 14A, 14B, and 14C. To form the plurality of source/drain regions 130, a semiconductor material may be epitaxially grown from a sidewall of each of the first to fourth nanosheets N1, N2, N3, and N4 and a surface of the fin-type active region F1, which are exposed at the plurality of recesses R1.

In implementations, to form the plurality of source/drain regions 130, a low-pressure chemical vapor deposition (LPCVD) process, a selective epitaxial growth (SEG) process, or a cyclic deposition and etching (CDE) process may be performed by using source materials including an element semiconductor precursor. The element semiconductor precursor may include a silicon (Si) source and a germanium (Ge) source.

In implementations, the plurality of source/drain regions 130 may include a SiGe layer doped with boron (B). In this case, to form the plurality of source/drain regions 130, boron (B) ions may be doped in-situ while supplying a Si source and a Ge source onto the substrate 102. Silane (SiH₄), disilane (Si₂H₆), trisilane (Si₃H₈), and/or dichlorosilane (SiH₂Cl₂) may be used as the Si source, without being limited thereto. Germane (GeH₄), digermane (Ge₂H₆), trigermane (Ge₃H₈), tetragermane (Ge₄H₁₀), and/or dichlorogermane (Ge₂H₂Cl₂) may be used as the Ge source, without being limited thereto. Diborane (B₂H₆), triborane, tetraborane, and/or pentaborane may be used as a B source, without being limited thereto.

In other implementations, the plurality of source/drain regions 130 may include a Si layer doped with phosphorus (P). In this case, to form the plurality of source/drain regions 130, phosphorus (P) ions may be doped in-situ while supplying a Si source onto the substrate 102. The Si source may be selected from the materials described above. Phosphine (PH₃) gas may be used as the phosphorus (P) ion source, without being limited thereto.

Afterwards, an insulating liner 142 may be formed to cover the resultant structure in which the plurality of source/drain regions 130 are formed, and an inter-gate dielectric film 144 may be formed on the insulating liner 142. A portion of each of the insulating liner 142 and the inter-gate dielectric film 144 may be etched to expose upper surfaces of a plurality of capping layers (refer to D126 in FIGS. 14A and 14C). Thereafter, the plurality of capping layers D126 may be removed to expose the dummy gate layer D124, and the insulating liner 142 and the inter-gate dielectric film 144 may be partially removed such that an upper surface of the inter-gate dielectric film 144 becomes at substantially the same level as an upper surface of the dummy gate layer D124.

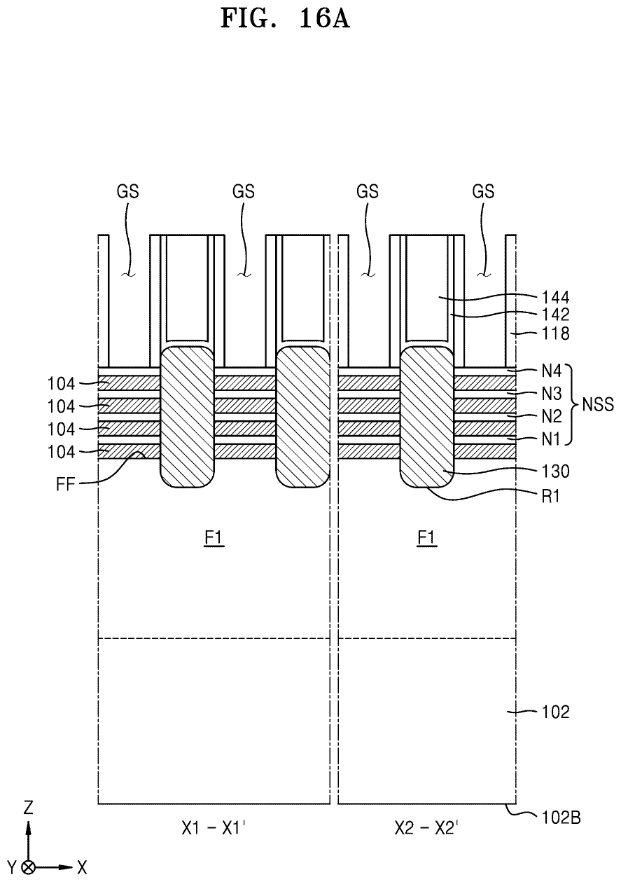

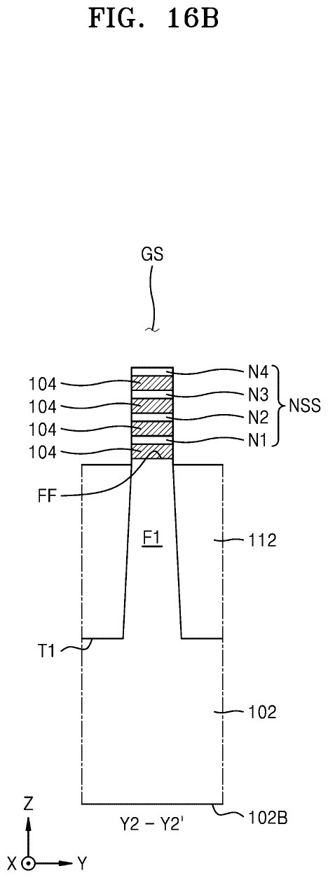

Referring to FIGS. 16A and 16B, the dummy gate layer D124 and the dummy oxide film D122 may be removed from the resultant structure of FIGS. 15A, 15B, and 15C to prepare a gate space GS.

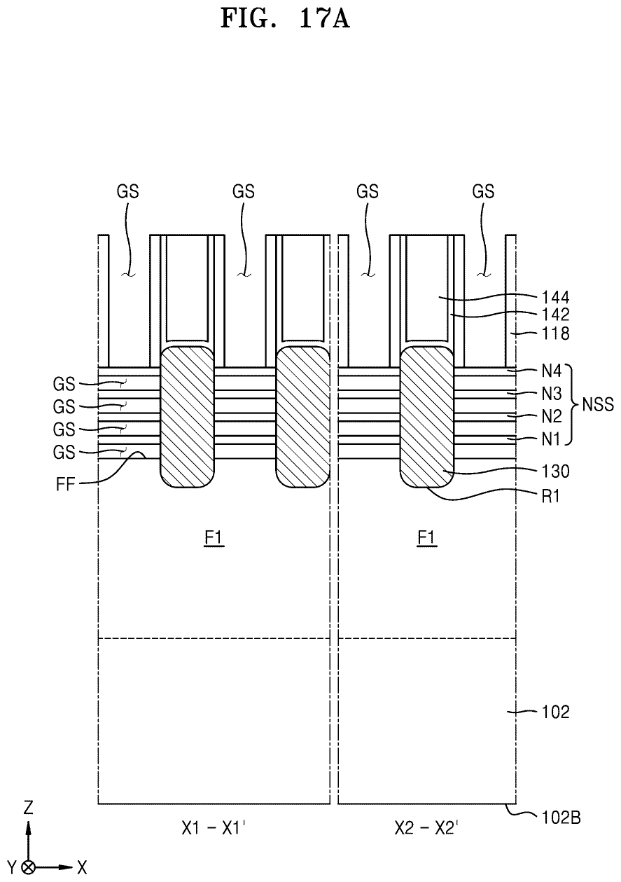

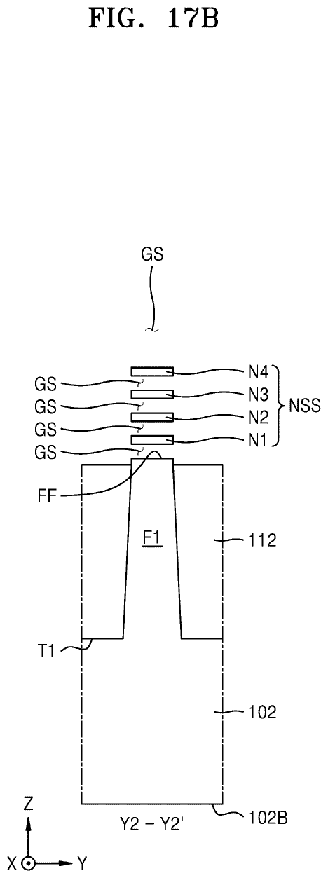

Referring to FIGS. 17A and 17B, in the resultant structure of FIGS. 16A and 16B, the plurality of sacrificial semiconductor layers 104 remaining on the substrate 102 may be selectively removed through the gate space GS. Thus, the gate space GS may extend to respective spaces between the first to fourth nanosheets N1, N2, N3, and N4 and a space between the first nanosheet N1 and the fin top surface FF of the fin-type active region F1.

In implementations, to selectively remove the plurality of sacrificial semiconductor layers 104, an etch selectivity of each of the first to fourth nanosheets N1, N2, N3, and N4 and the fin-type active region F1 with respect to the plurality of sacrificial semiconductor layers 104 may be used. A liquid or gaseous etchant may be used to selectively remove the plurality of sacrificial semiconductor layers 104. In implementations, to selectively remove the plurality of sacrificial semiconductor layers 104, a CH₃COOH-based etchant, for example, an etchant including a mixture of CH₃COOH, HNO₃, and HF or an etchant including a mixture of CH₃COOH, H₂O₂, and HF may be used, without being limited thereto.

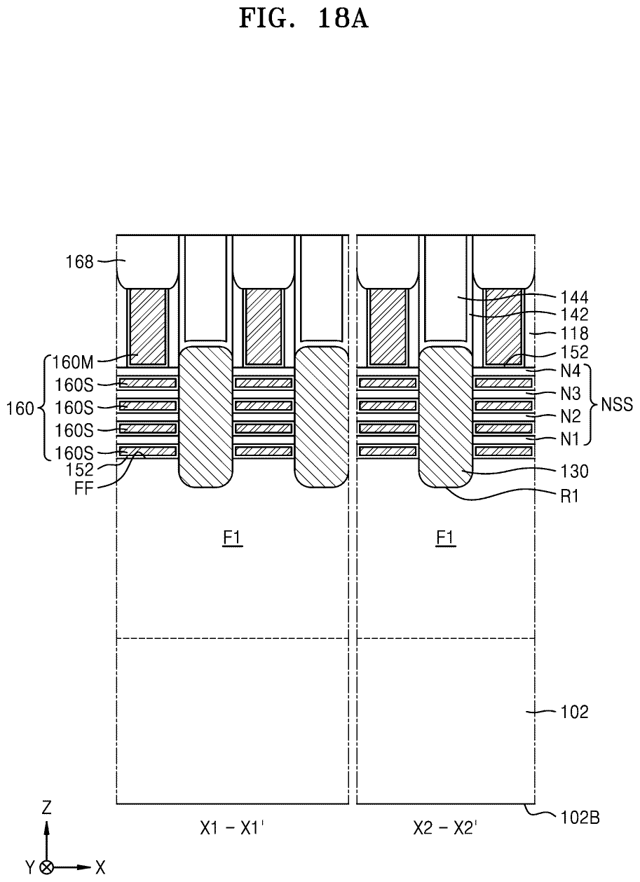

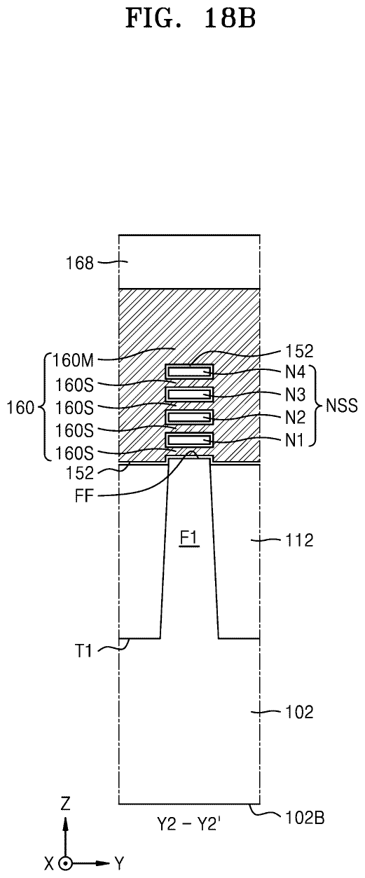

Referring to FIGS. 18A and 18B, in the resultant structure of FIGS. 17A and 17B, a gate dielectric film 152 may be formed to cover respective exposed surfaces of the first to fourth nanosheets N1, N2, N3, and N4 and the fin-type active region F1. To form the gate dielectric film 152, an atomic layer deposition (ALD) process may be used.

Afterwards, a gate line 160 filling the gate space (refer to GS in FIGS. 17A and 17B) may be formed on the gate dielectric film 152. Thereafter, a height of each of the gate line 160, the gate dielectric film 152, and the insulating spacer 118 may be reduced by removing a portion of each of the gate line 160, the gate dielectric film 152, and the insulating spacer 118 from an upper surface of each thereof, and a plurality of capping insulating patterns 168 may be formed to cover the upper surface of each of the gate line 160, the gate dielectric film 152, and the insulating spacer 118.

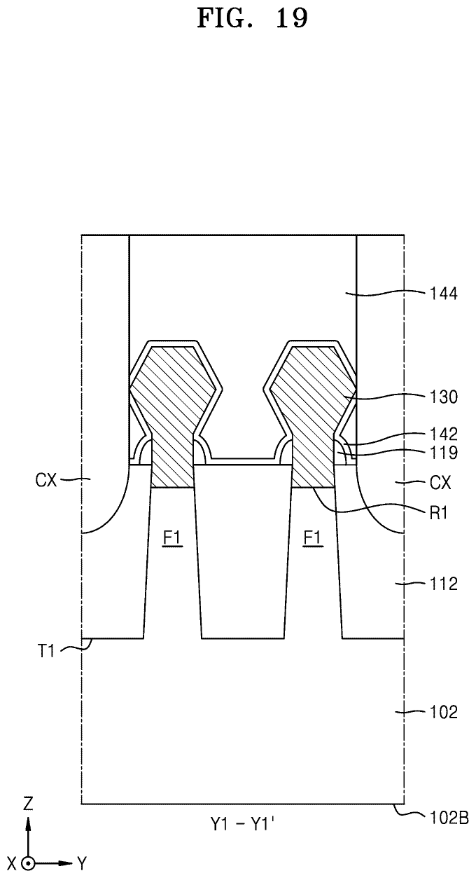

Referring to FIG. 19, in the resultant structure of FIGS. 18A and 18B, a partial region of each of the inter-gate dielectric film 144 and the insulating liner 143 between every two adjacent ones of the plurality of gate lines 160 may be removed by using an anisotropic dry etching process to expose the device isolation film 112. Partial regions of the exposed device isolation film 112 may be removed by using an anisotropic etching process to form a plurality of contact isolation spaces. Thereafter, the plurality of contact isolation spaces a plurality of contact isolation insulating structures CX may be formed to fill the plurality of contact isolation spaces.

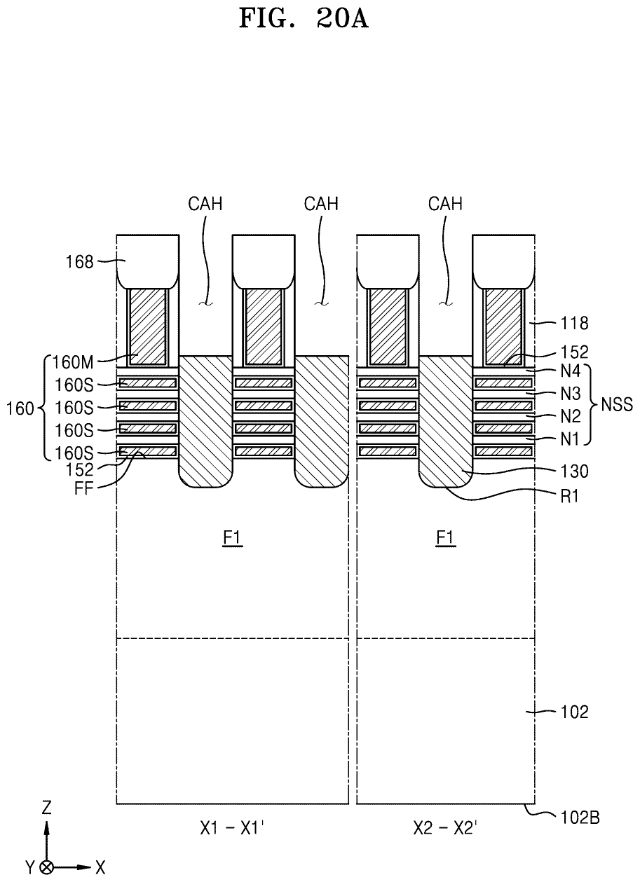

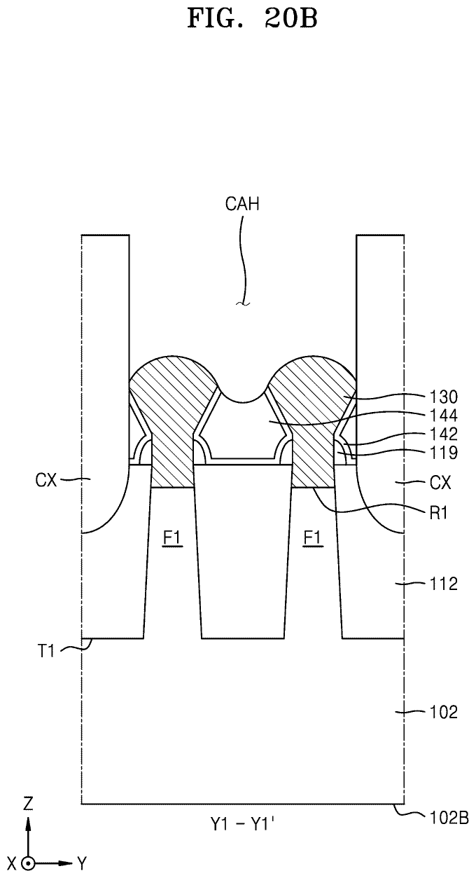

Referring to FIGS. 20A and 20B, respective portions of the insulating liner 142 and the inter-gate dielectric film 144 may be removed from the resultant structure in which the plurality of contact isolation insulating structures CX are formed. Thus, a plurality of source/drain contact holes CAH may be formed to expose the plurality of source/drain regions 130. After the plurality of source/drain contact holes CAH are formed, frontside surfaces of the source/drain regions 130 exposed through the plurality of source/drain contact holes CAH may be partially removed.

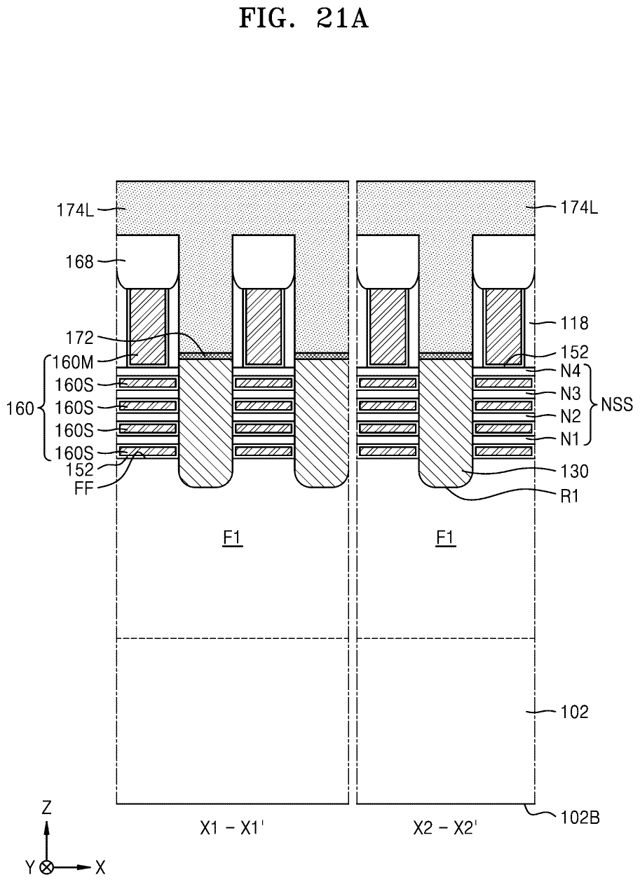

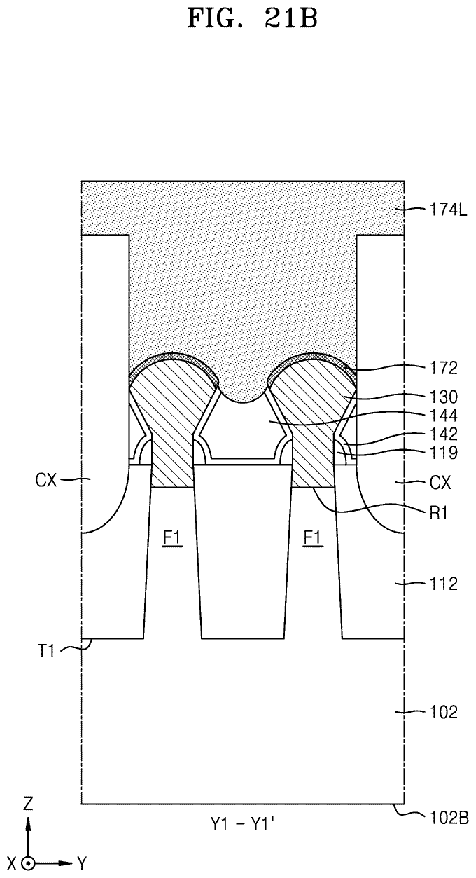

Referring to FIGS. 21A and 21B, in the resultant structure of FIGS. 20A and 20B, a metal silicide film 172 may be formed to cover the frontside surfaces of the source/drain regions 130 exposed through the plurality of source/drain contact holes CAH, and a metal-containing layer 174L filling the plurality of source/drain contact holes CAH may be formed on the metal silicide film 172.

The metal-containing layer 174L may include materials required for forming a plurality of source/drain contacts (refer to 174 in FIGS. 3, 4, 6, and 7). For example, to form the metal-containing layer 174L, a conductive barrier film may be formed, and a metal plug may be then formed on the conductive barrier film. Detailed configurations of the conductive barrier film and the metal plug, which are required for forming the plurality of source/drain contacts 174, may be understood by reference to constituent materials of the plurality of source/drain contacts 174, which are described above with reference to FIGS. 3, 5, and 7. When the metal-containing layer 174L is formed, the process of forming the conductive barrier film may be omitted.

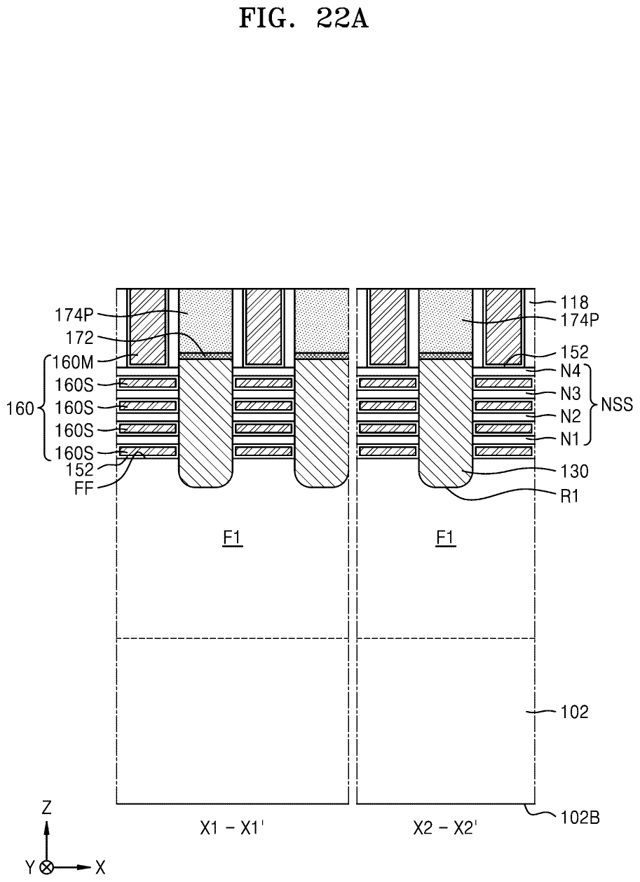

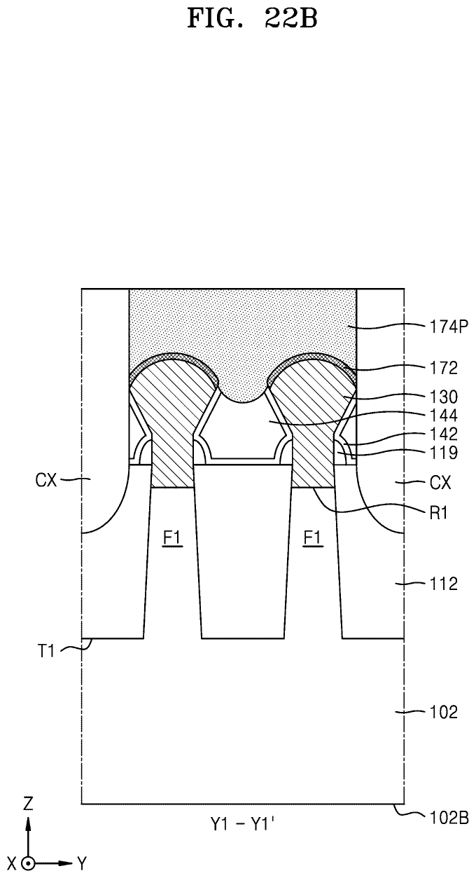

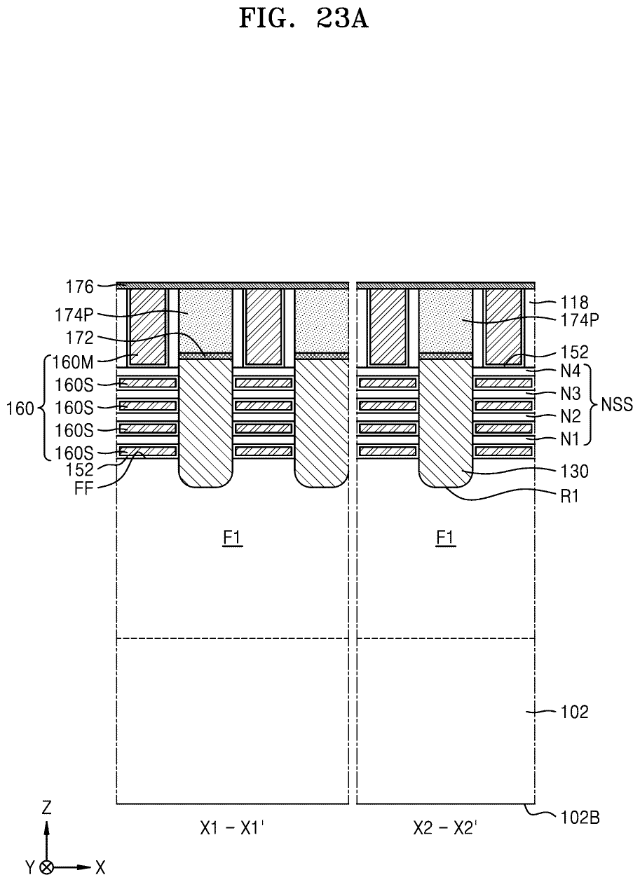

Referring to FIGS. 22A and 22B, in the resultant structure of FIGS. 21A and 21B, the plurality of capping insulating patterns 168 may be removed to expose the plurality of gate lines 160, and the obtained resultant structure may be planarized to separate the metal-containing layer 174L into a plurality of metal-containing patterns 174P. During the planarization process, a height of each of a plurality of gate dielectric films 152 and the plurality of insulating spacers 118 in a vertical direction (Z direction) may also be reduced.

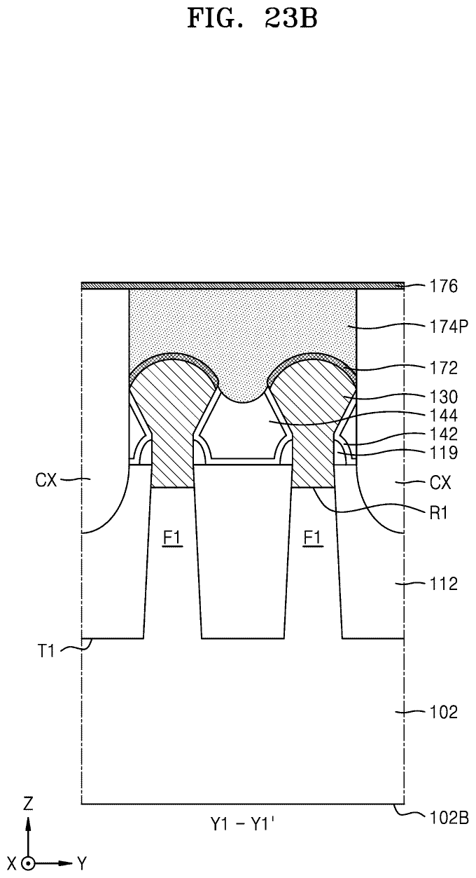

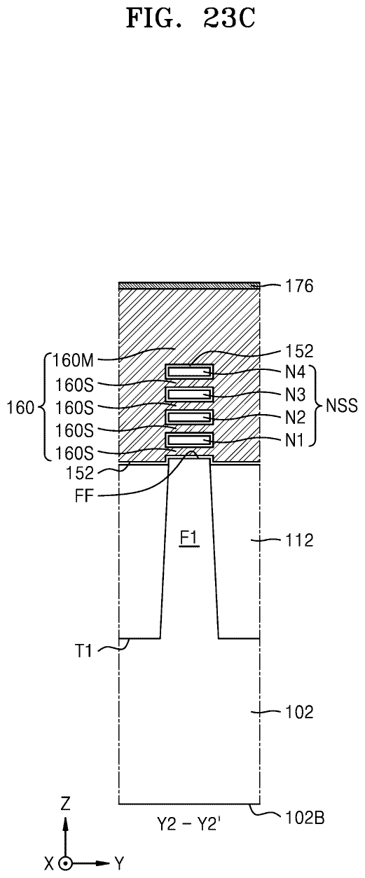

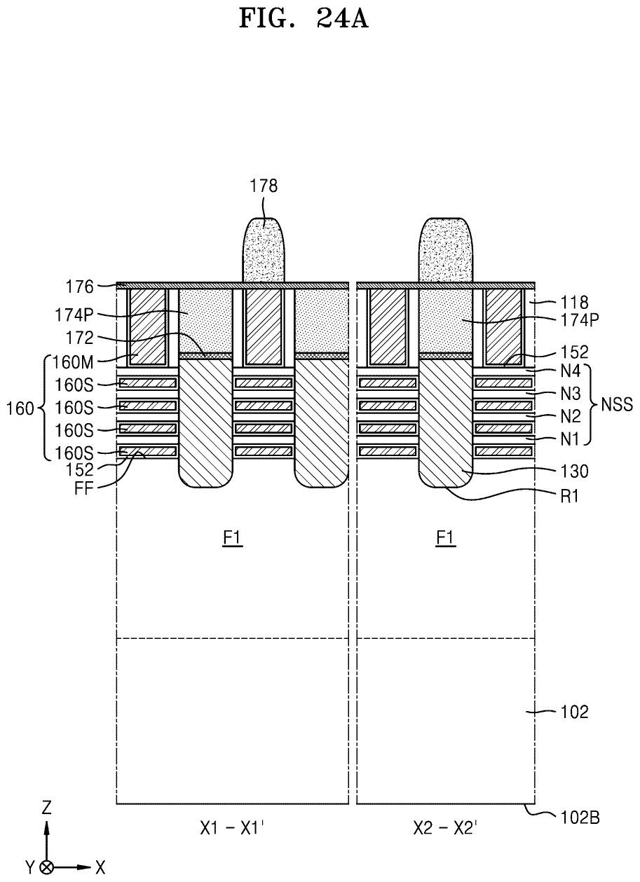

Referring to FIGS. 23A, 23B, and 23C, a metal-containing conductive liner 176 may be formed on the resultant structure on which the planarization process has been performed in FIGS. 22A and 22B. A constituent material of the metal-containing conductive liner 176 may be the same as a constituent material of the first metal-containing conductive liner 176A and the second metal-containing conductive liner 176B, which has been described with reference to FIGS. 3 to 7.

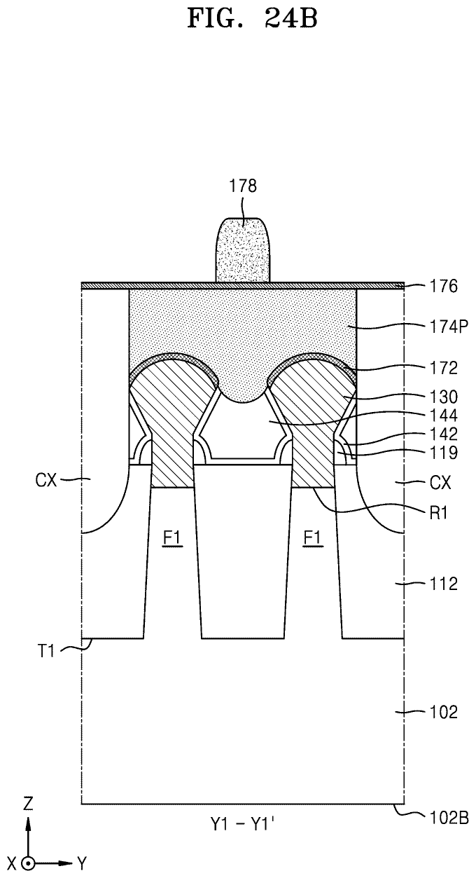

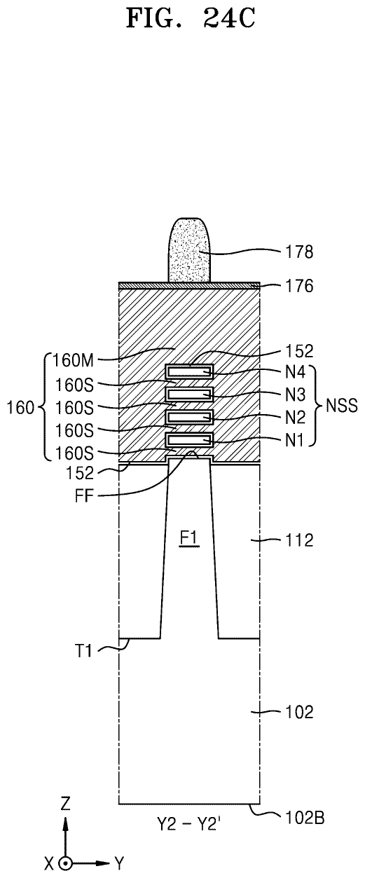

Referring to FIGS. 24A, 24B, and 24C, a plurality of sacrificial pillars 178 may be formed on the metal-containing conductive liner 176. Some of the plurality of sacrificial pillars 178 may be formed at a position overlapping the metal-containing pattern 174P in the vertical direction (Z direction) to cover a region of the metal-containing conductive liner 176, which corresponds to a region where a plurality of source/drain via contacts (refer to VA in FIG. 2) will be formed. Some others of the plurality of sacrificial pillars 178 may be formed at a position overlapping the gate line 160 in the vertical direction (Z direction) to cover a region of the metal-containing conductive liner 176, which corresponds to a region where a plurality of the gate contacts (refer to CB in FIG. 2) will be formed. In implementations, when the metal-containing conductive liner 176 includes TiN, the plurality of sacrificial pillars 178 may each include a silicon oxide film.

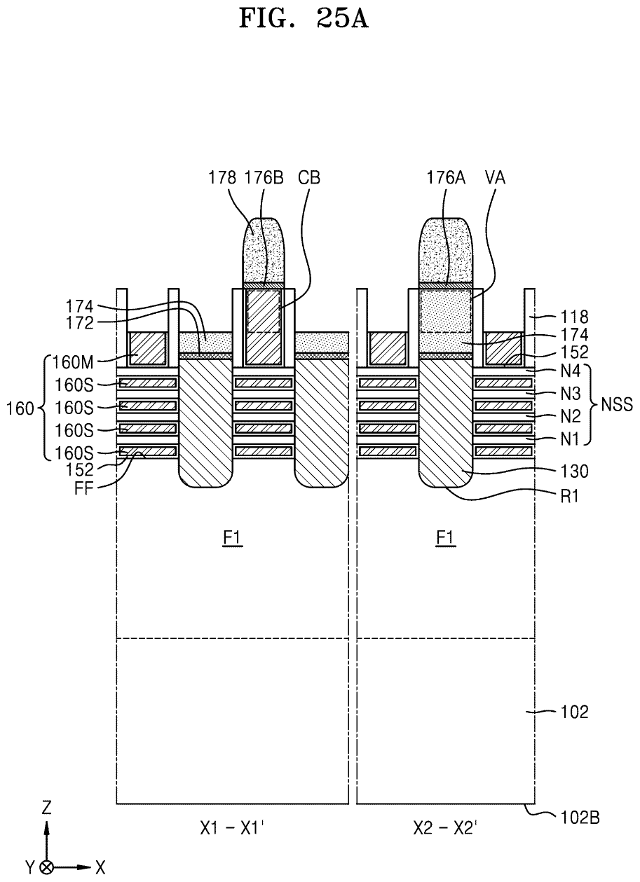

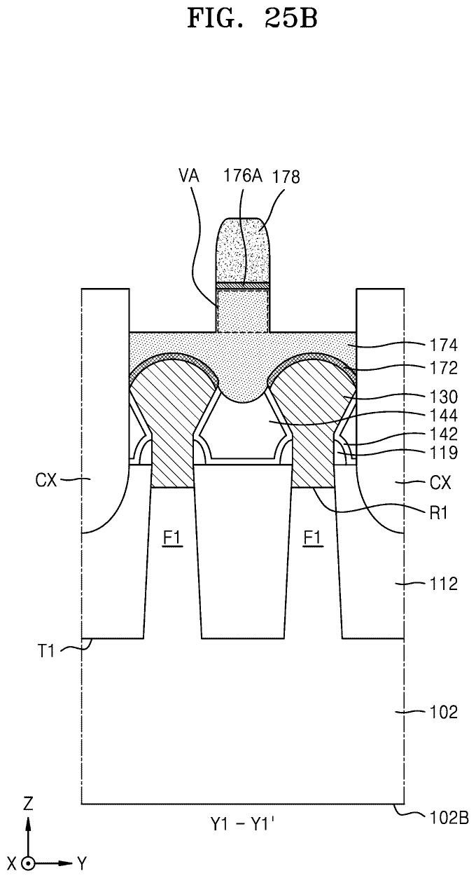

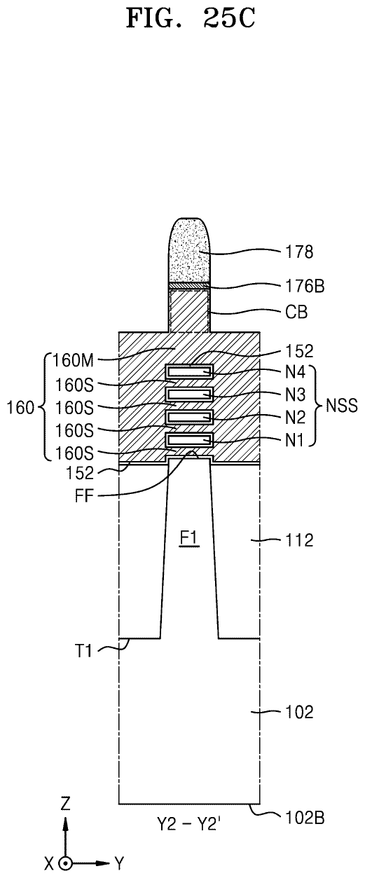

Referring to FIGS. 25A, 25B, and 25C, in the resultant structure of FIGS. 24A, 24B, and 24C, the metal-containing conductive liner 176 may be selectively etched by means of an anisotropic dry etching process by using the plurality of sacrificial pillars 178 as an etch mask, and thus, a plurality of first and second metal-containing conductive liners 176A and 176B may be formed from the metal-containing conductive liner 176. Subsequently, a portion of each of the exposed gate lines 160 and a portion of each of the metal-containing patterns 174P may be selectively etched by using an anisotropic dry etching process. As a result, each of portions of the plurality of gate lines 160 that are covered by the plurality of sacrificial pillars 178 may be left as a structure including the gate contact CB, and each of portions of the plurality of gate lines 160 that are not covered by the plurality of sacrificial pillars 178 may be left as the gate line 160 with a reduced thickness in the vertical direction (Z direction). In addition, portions of the plurality of metal-containing patterns 174P, which are covered by the plurality of sacrificial pillars 178, may be left as a structure including a plurality of source/drain via contacts VA, and portions of the plurality of metal-containing patterns 174P, which are not covered by the plurality of sacrificial pillars 178, may be reduced in thickness in the vertical direction (Z direction) and left as a plurality of source/drain contacts 174.

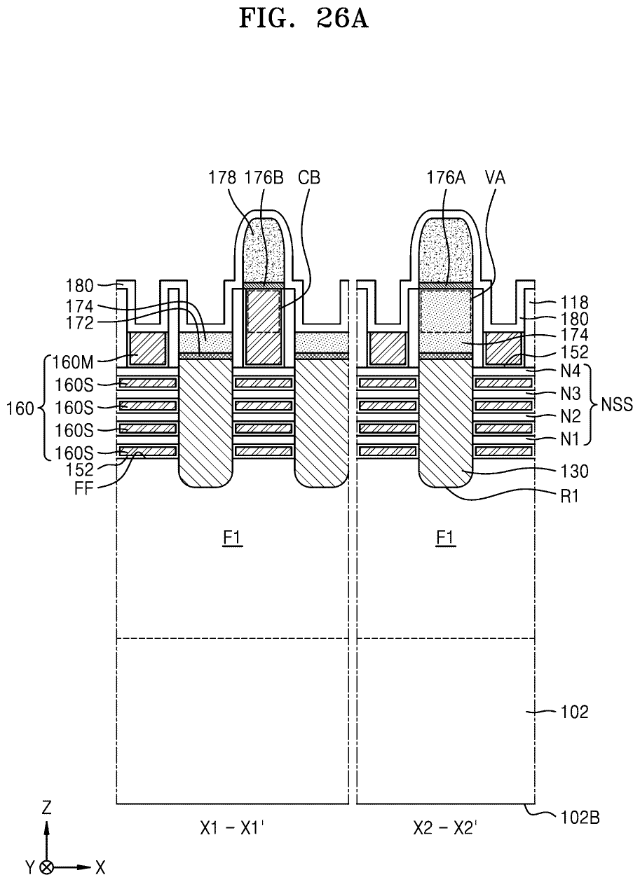

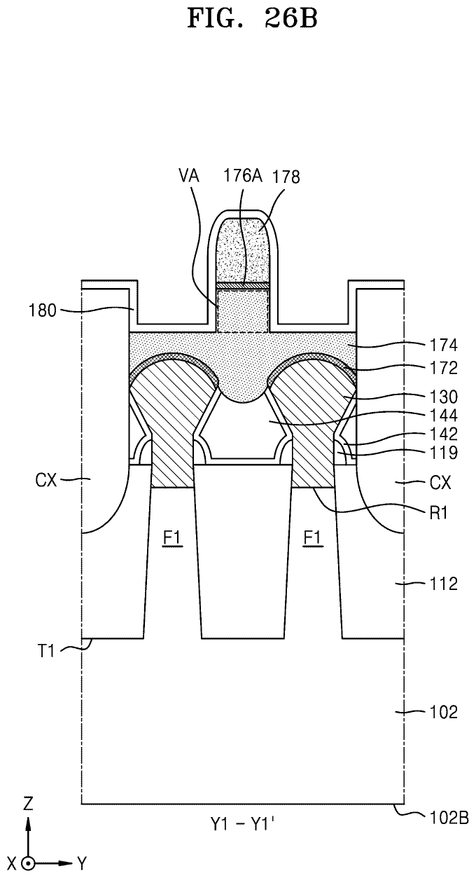

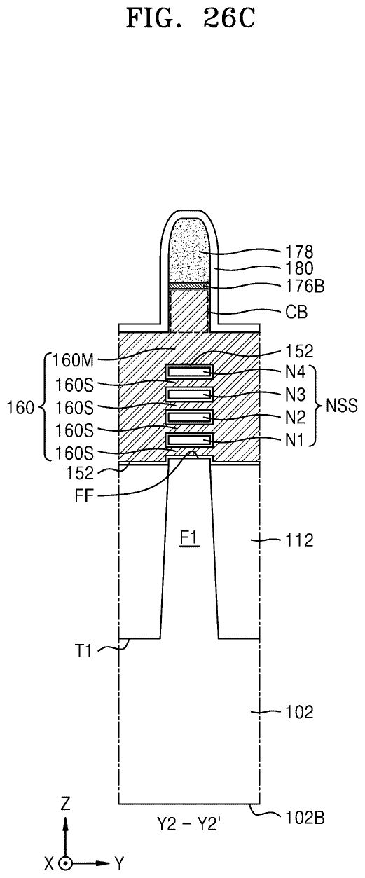

Referring to FIGS. 26A, 26B, and 26C, an insulating barrier wall layer 180 may be formed to conformally cover the exposed surfaces of the resultant structure of FIGS. 25A, 25B, and 25C. A constituent material of the insulating barrier wall layer 180 may be the same as a constituent material of the first insulating barrier wall 180A and the second insulating barrier wall 180B, which has been described with reference to FIGS. 3 to 7.

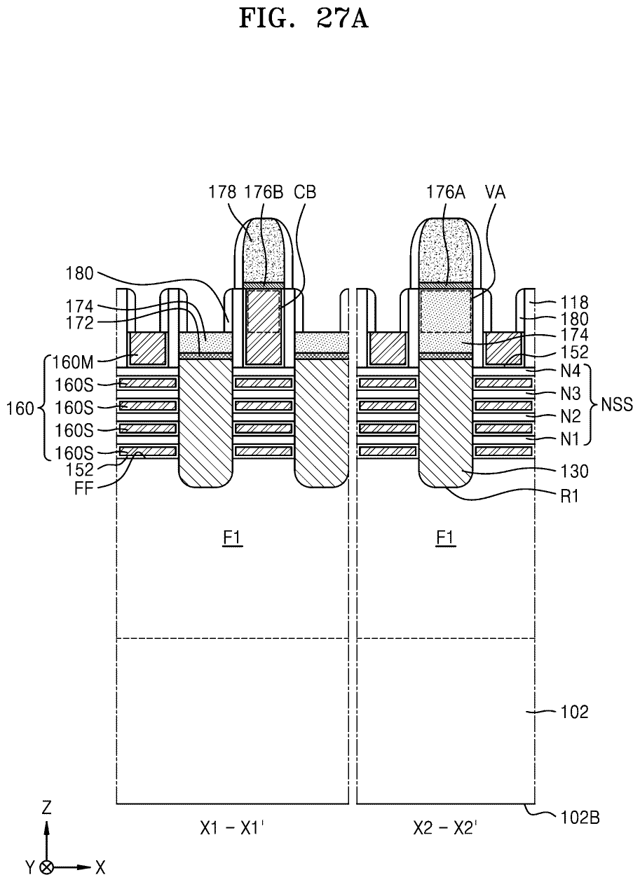

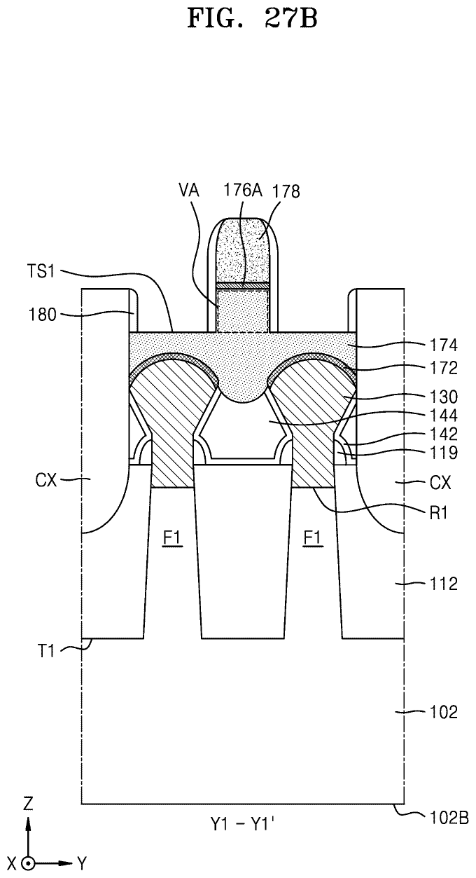

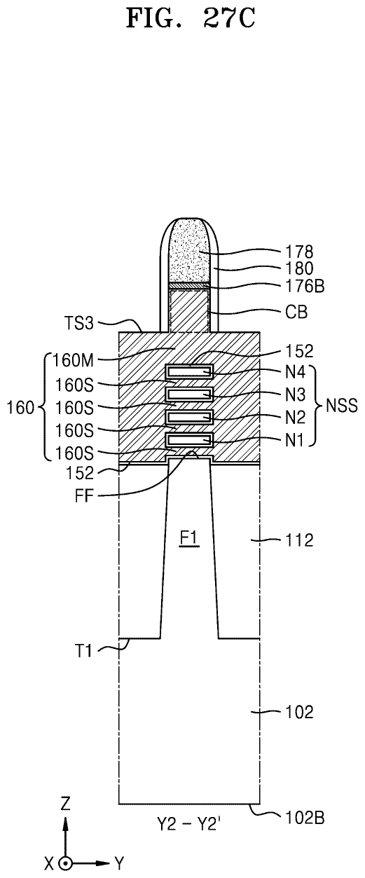

Referring to FIGS. 27A, 27B, and 27C, in the resultant structure of FIGS. 26A, 26B, and 26C, the insulating barrier wall layer 180 may be partially etched back to expose a first upper surface TS1 of each of the plurality of source/drain contacts 174 and a third upper surface TS3 of each of the plurality of gate lines 160. After the first upper surface TS1 of each of the plurality of source/drain contacts 174 and the third upper surface TS3 of each of the plurality of gate lines 160 are exposed, only portions of the insulating barrier wall layer 180, which cover sidewalls of each of lower structures covered by the insulating barrier wall layer 180, may be left.

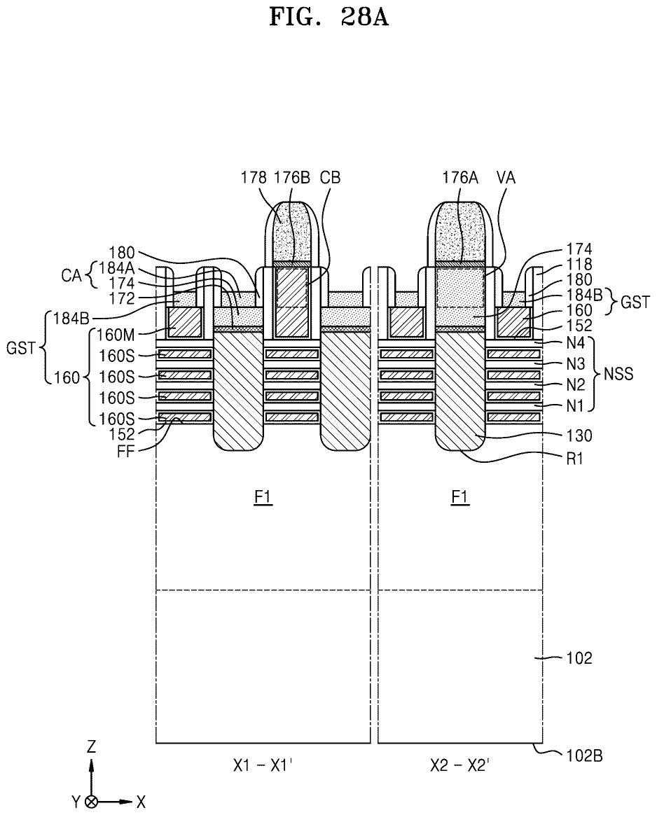

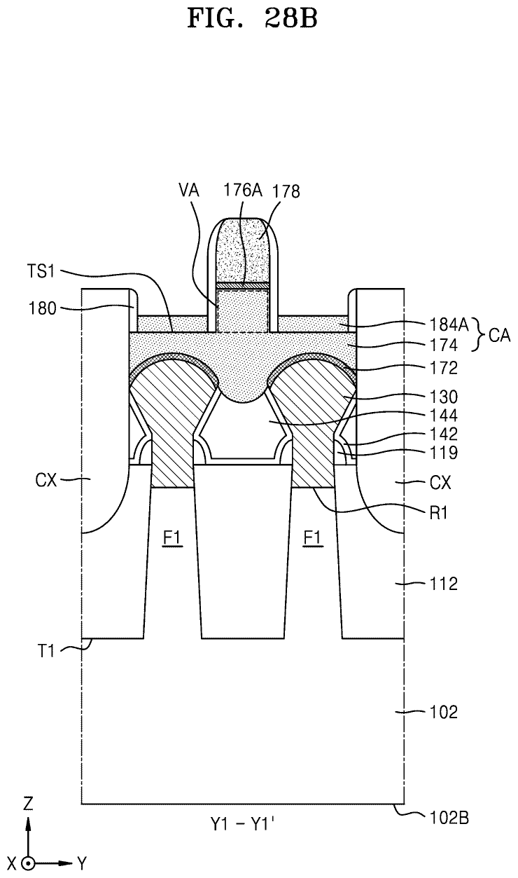

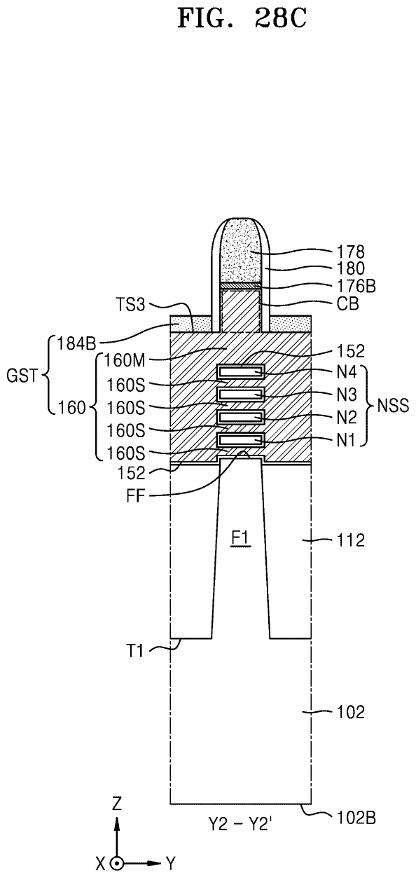

Referring to FIGS. 28A, 28B, and 28C, a source/drain contact extension 184A may be formed to cover the first upper surface TS1 of each of the plurality of source/drain contacts 174 exposed through the insulating barrier wall layer 180, and a gate extension 184B may be formed to cover the third upper surface TS3 of each of the plurality of gate lines 160.

In implementations, to form the source/drain contact extension 184A and the gate extension 184B, a process of selectively depositing a metal film in a bottom-up manner only on the first upper surface TS1 of each of the plurality of source/drain contacts 174 and the third upper surface TS3 of each of the plurality of gate lines 160 in the vertical direction (Z direction) may be performed based on differences between deposition characteristics of the metal film on the first upper surface TS1 and the third upper surface TS3 and deposition characteristics of the metal film on a surface of each of the insulating barrier wall layer 180 and the plurality of sacrificial pillars 178. The bottom-up deposition process may be performed by using a chemical vapor deposition (CVD) process.

During the bottom-up deposition process of forming the source/drain contact extension 184A and the gate extension 184B, a sufficient insulation distance may be ensured by the insulating spacer 118 and the insulating barrier wall layer 180 between the source/drain contact extension 184A and the gate line 160 arranged adjacent thereto. Accordingly, the possibility of undesired short-circuits may be blocked during the bottom-up deposition process of forming the source/drain contact extension 184A and the gate extension 184B.

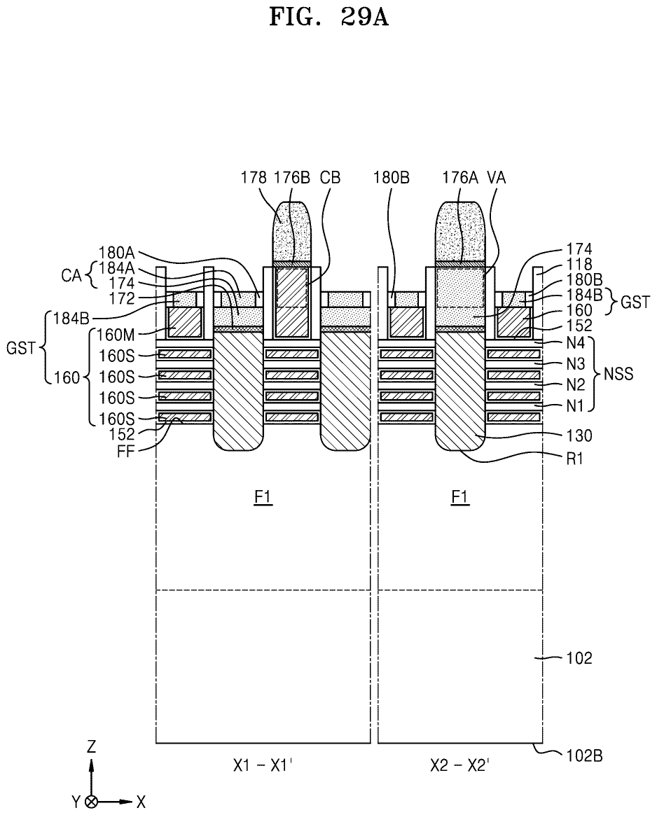

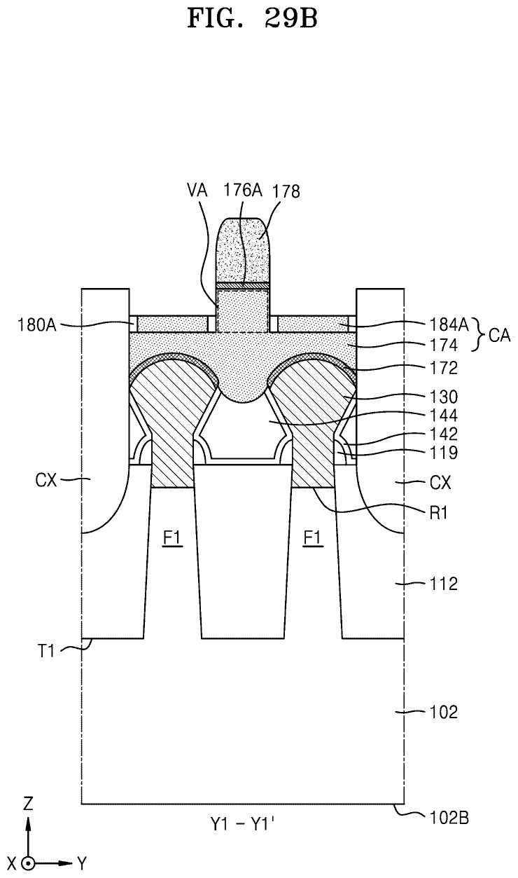

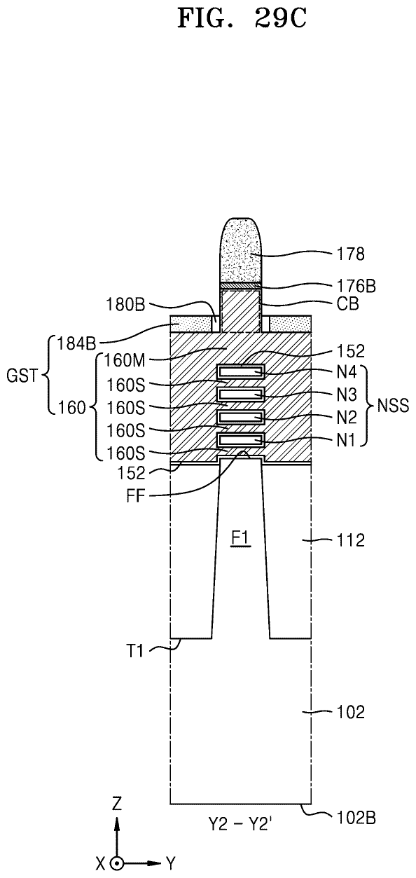

Referring to FIGS. 29A, 29B, and 29C, in the resultant structure of FIGS. 28A, 28B, and 28C, the insulating barrier wall layer 180 may be partially and selectively etched back to remove portions of the insulating barrier wall layer 180, which protrude over adjacent ones of source/drain contact extensions 184A and adjacent ones of gate extensions 184B. As a result, first insulating barrier walls 180A covering sidewalls of the source/drain contact extension 184A and second insulating barrier walls 180B covering sidewalls of the gate extension 184B may be formed from the insulating barrier wall layer 180.

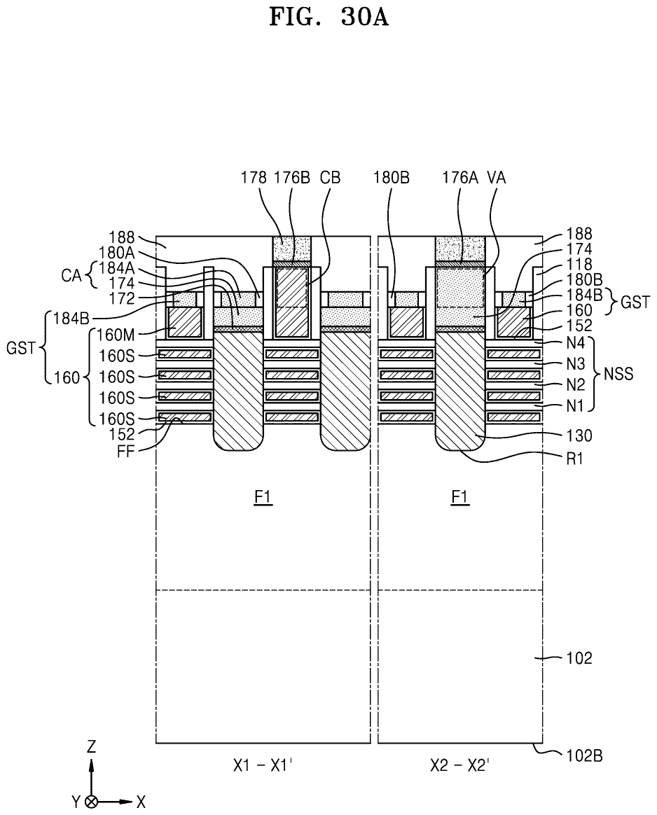

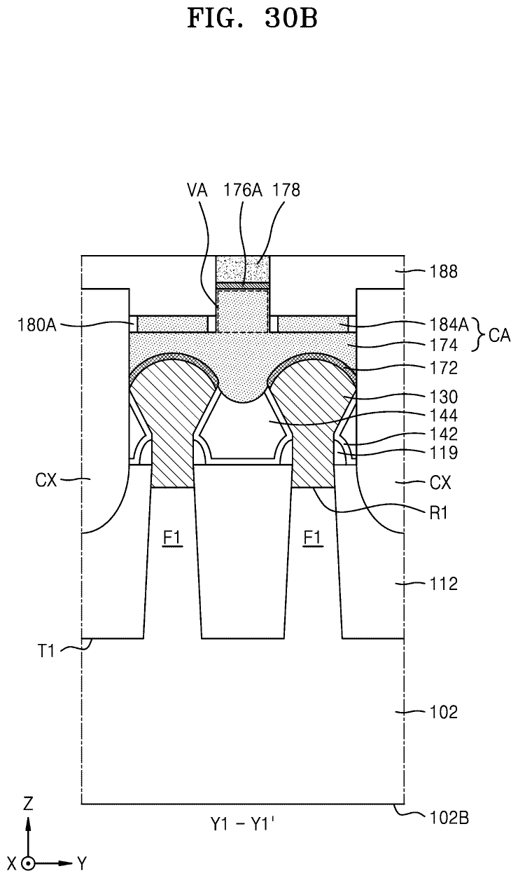

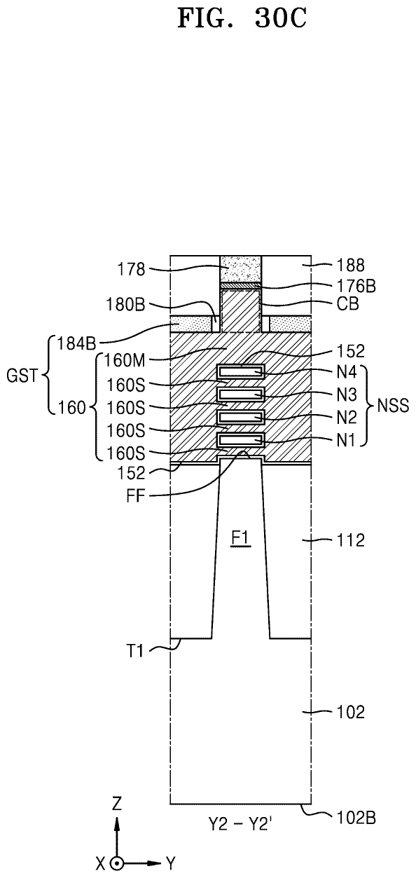

Referring to FIGS. 30A, 30B, and 30C, a capping insulating film 188 may be formed to cover the resultant structure of FIGS. 29A, 29B, and 29C, and the obtained resultant structure may be planarized to expose the plurality of sacrificial pillars 178.

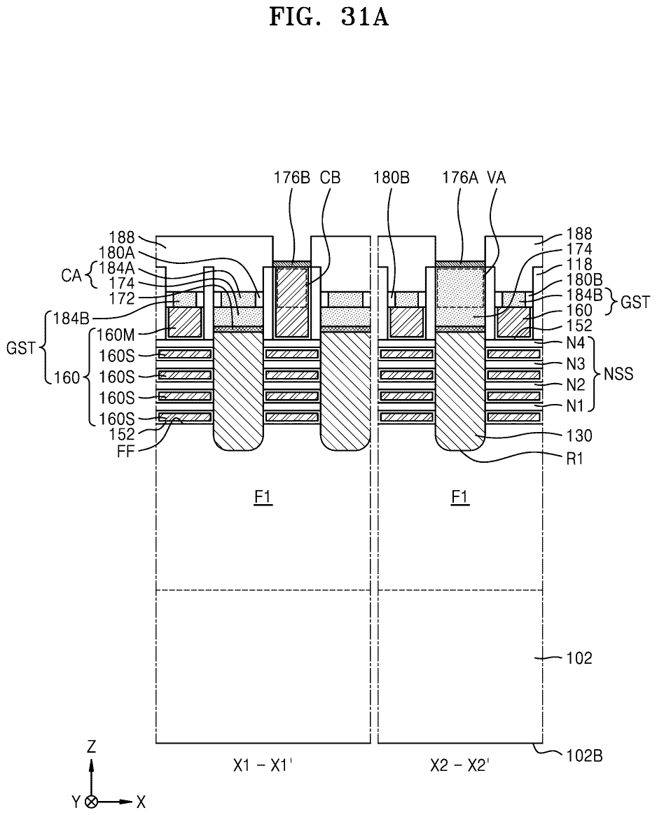

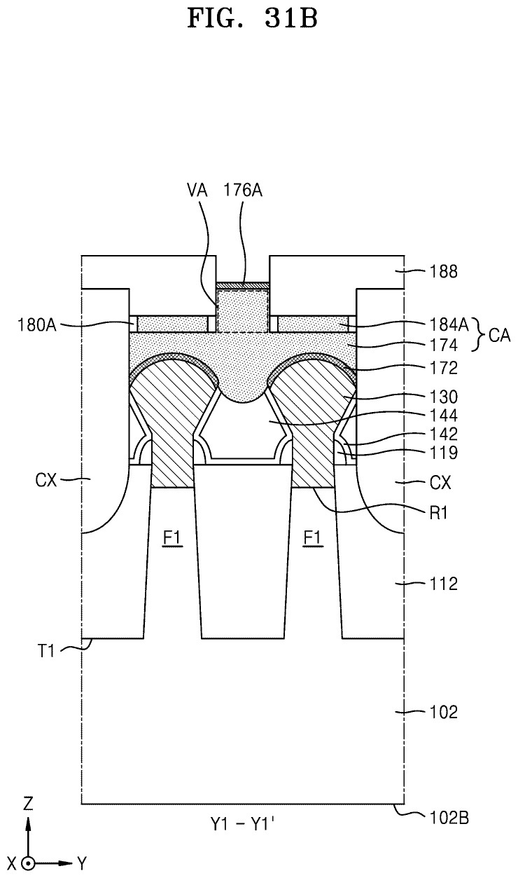

Referring to FIGS. 31A, 31B, and 31C, the plurality of sacrificial pillars 178 may be selectively removed from the resultant structure of FIGS. 30A, 30B, and 30C, and thus, the plurality of first and second metal-containing conductive liners 176A and 176B may be exposed through the capping insulating film 188.

Afterwards, a wiring structure MST including a plurality of first wiring layers 190 may be formed to cover upper surfaces of the plurality of first and second metal-containing conductive liners 176A and 176B and the capping insulating film 188. Thus, the IC device 100 described with reference to FIGS. 2 to 7 may be manufactured.

To manufacture the IC device 200 illustrated in FIG. 8, the processes described with reference to FIGS. 11A to 31C may be used. However, during the processes described with reference to FIGS. 25A, 25B, and 25C, respective portions of the plurality of metal-containing patterns 174P may be selectively etched by using a dry anisotropic etching process to form a plurality of source/drain via contacts VA2 and a plurality of source/drain contacts 274. In addition, during the processes described with reference to FIGS. 28A, 28B, and 28C, a source/drain contact extension 284A covering a first upper surface TS21 of each of the plurality of source/drain contacts 274 and a metal silicide film 172 may be formed instead of the source/drain contact extension 184A.

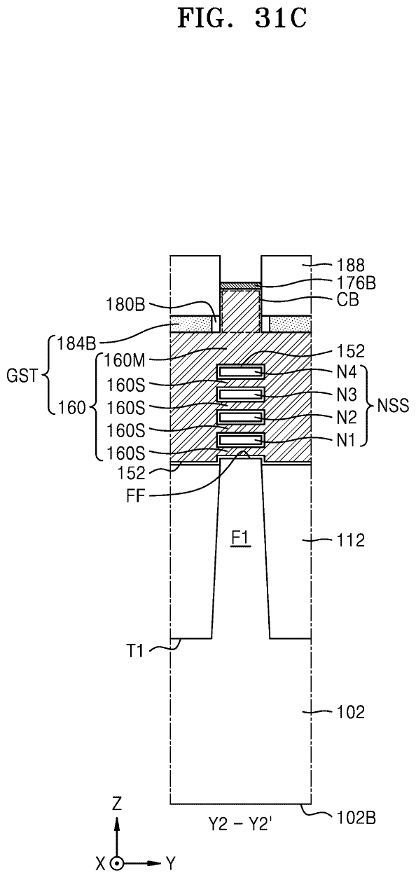

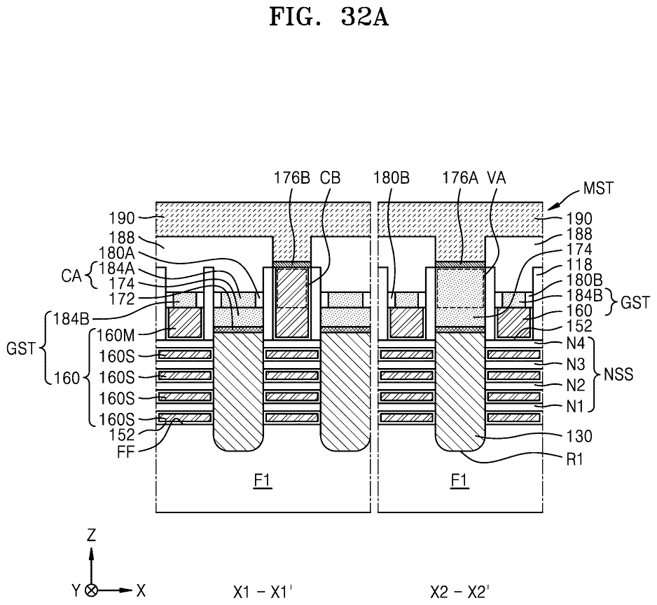

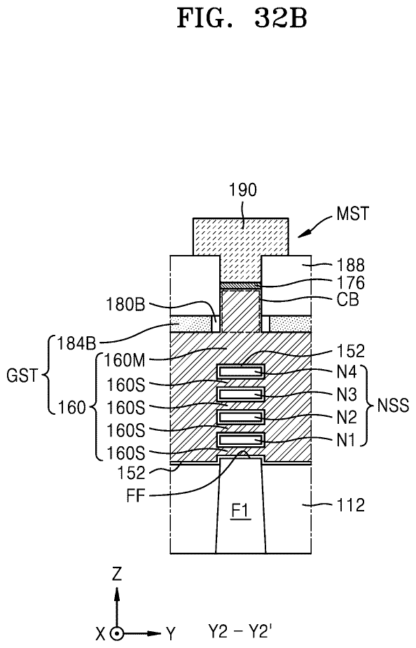

FIGS. 32A to 38 are diagrams illustrating a process sequence of a method of manufacturing an IC device, according to implementations. More specifically, FIGS. 32A, 33A, 34A, and 35 to 38 are cross-sectional views of examples of cross-sectional structures of a portion corresponding to a cross-section taken along line X1-X1′ of FIG. 2 and a cross-section taken along line X2-X2′ of FIG. 2, according to the process sequence. FIGS. 32B, 33B, and 34B are cross-sectional views of examples of cross-sectional structures of a portion corresponding to a cross-section taken along line Y2-Y2′ of FIG. 2, according to the process sequence. An example of a method of manufacturing the IC device 300 illustrated in FIG. 9 is described with reference to FIGS. 32A to 38. In FIGS. 32A to 38, the same reference numerals are used to denote the same elements as in FIGS. 2 to 31C, and thus, any redundant description thereof is omitted.

Referring to FIGS. 32A and 32B, in the structure described with reference to FIGS. 2 to 7, a portion of a substrate 102 may be removed from a backside surface 102B of the substrate 102 to expose the plurality of fin-type active regions F1 and the device isolation film 112, and respective exposed portions of the plurality of fin-type active regions F1 and the device isolation film 112 may be further removed to reduce a thickness of each of the plurality of fin-type active regions F1 and the device isolation film 112 in a vertical direction (Z direction).

In implementations, the process of removing the substrate 102 and the process of removing the respective portions of the plurality of fin-type active regions F1 and the device isolation film 112 may be performed by using at least one selected from a mechanical grinding process, a chemical mechanical polishing (CMP) process, a wet etching process, and a combination thereof.

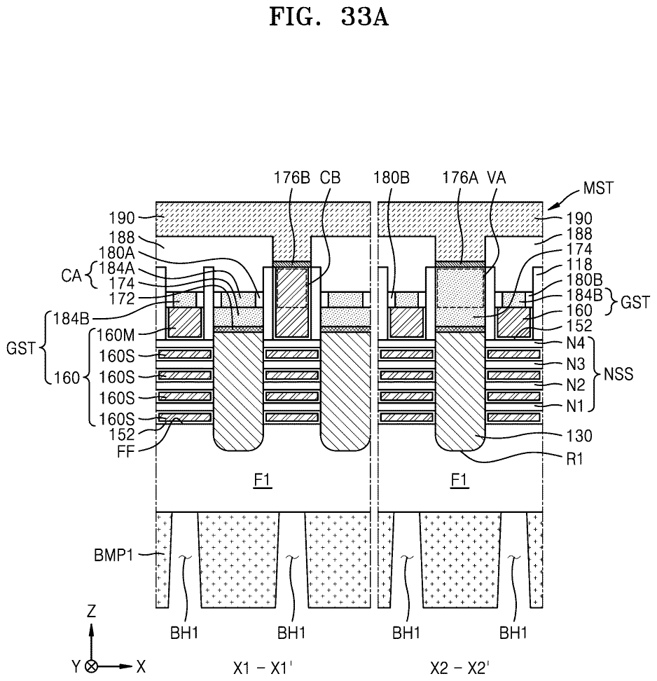

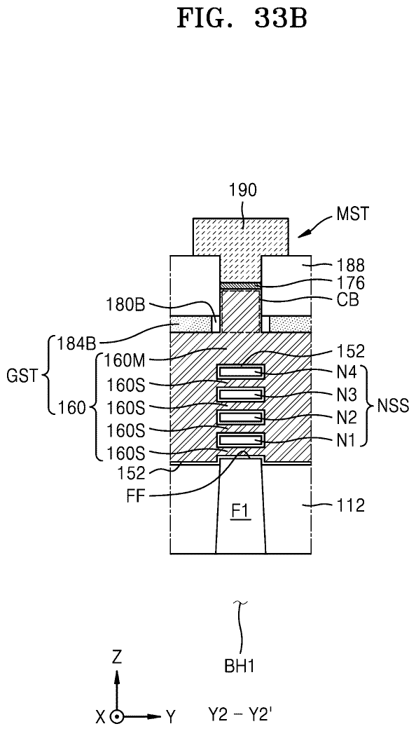

Referring to FIGS. 33A and 33B, in the resultant structure of FIGS. 32A and 32B, a first backside mask pattern BMP1 may be formed on exposed backside surfaces of the plurality of fin-type active regions F1 and the device isolation film 112. The first backside mask pattern BMP1 may have a plurality of line-shaped openings BH1 extending lengthwise in a second lateral direction (Y direction). Respective portions of the plurality of fin-type active regions F1 and the device isolation film 112 may be exposed through the plurality of line-shaped openings BH1 of the first backside mask pattern BMP1. In implementations, the first backside mask pattern BMP1 may include a spin-on-hardmask (SOH) material, without being limited thereto.

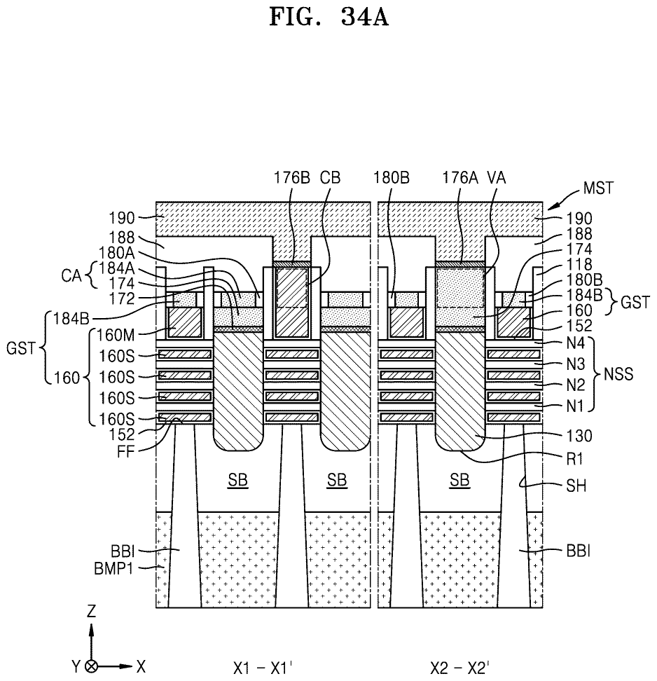

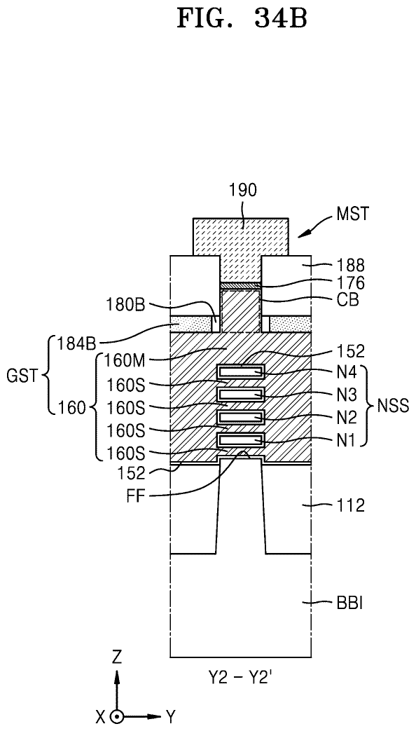

Referring to FIGS. 34A and 34B, in the resultant structure of FIGS. 33A and 33B, the plurality of fin-type active regions F1 may be selectively etched by using the first backside mask pattern BMP1 as an etch mask to form a plurality of vertical holes SH, each of which exposes a gate dielectric film 152. By forming the plurality of vertical holes SH, each of the plurality of fin-type active regions F1 may be divided into a plurality of semiconductor blocks SB.

Thereafter, a plurality of backside bulk insulating films BBI may be formed to fill the plurality of vertical holes SH and the plurality of line-shaped openings BH1. In implementations, the plurality of backside bulk insulating films BBI may be formed by using an ALD process or a CVD process, without being limited thereto.

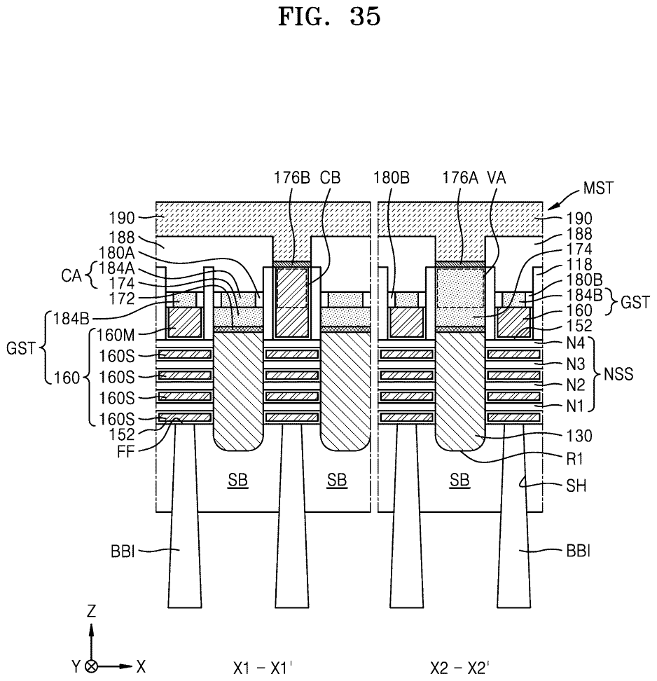

Referring to FIG. 35, the first backside mask pattern BMP1 may be removed from the resultant structure of FIGS. 34A and 34B. When the first backside mask pattern BMP1 includes a SOH material, the first backside mask pattern BMP1 may be removed by using ashing and stripping processes.

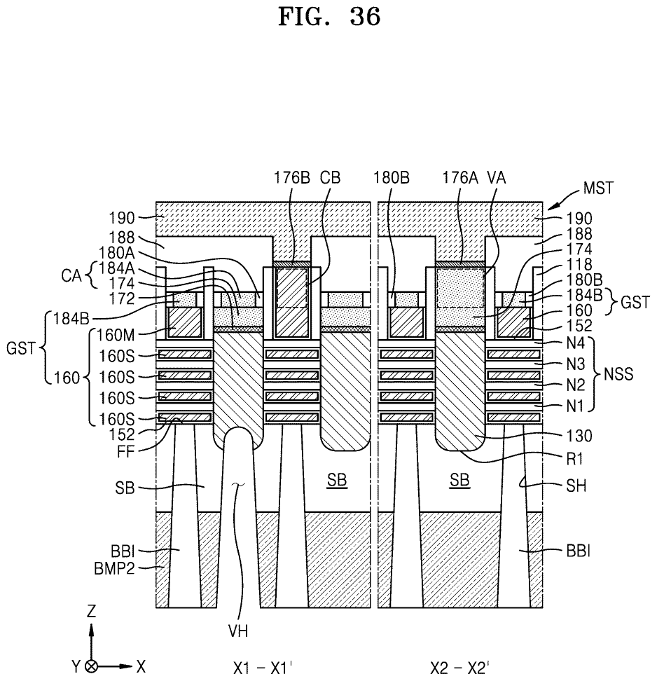

Referring to FIG. 36, the resultant structure on which the process described with reference to FIG. 35 has been performed may be coated with a SOH material to form a planarized hardmask film. The hardmask film may be patterned to form a second backside mask pattern BMP2 having a hole exposing the semiconductor block SB. Thereafter, the semiconductor block SB may be etched by using the second backside mask pattern BMP2 as an etch mask to form a via hole VH exposing the backside surface of the source/drain region 130. During the formation of the via hole VH, a portion of the source/drain region 130 may be etched, and thus, the via hole VH may extend into the source/drain region 130.

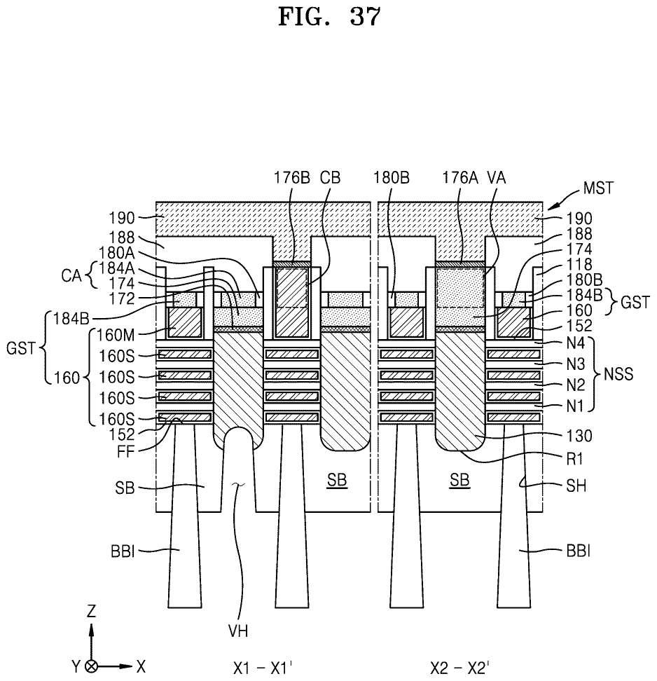

Referring to FIG. 37, the second backside mask pattern BMP2 may be removed from the resultant structure of FIG. 36. When the second backside mask pattern BMP2 includes a SOH material, the second backside mask pattern BMP2 may be removed by using ashing and stripping processes.

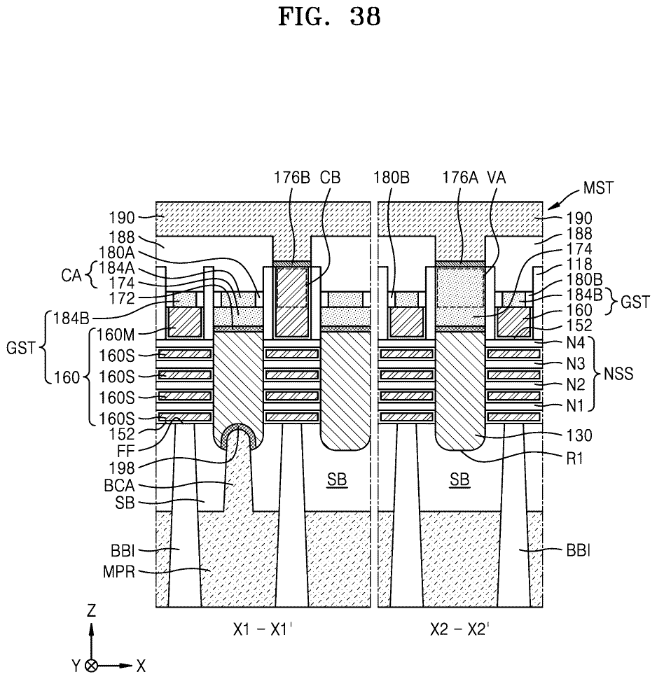

Referring to FIG. 38, in the resultant structure of FIG. 37, a space between the via hole VH and the backside bulk insulating film BBI may be filled by a conductive material to form a backside source/drain contact BCA and a backside power rail MPR. Thus, the IC device 300 illustrated in FIG. 9 may be manufactured.

Although examples of the methods of manufacturing the IC device 100 illustrated in FIGS. 2 to 7, the IC device 200 illustrated in FIG. 8, and the IC device 300 illustrated in FIG. 9 have been described with reference to FIGS. 11A to 38, it will be understood that IC devices having variously changed structures of the IC devices 100, 200, and 300 may be manufactured by applying various modifications and changes to the processes described with reference to FIGS. 11A to 38 within the scope of the present disclosure.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. An integrated circuit device comprising:
a fin-type active region extending in a first lateral direction;
a channel region on the fin-type active region;
a gate line surrounding the channel region;
a source/drain region on the fin-type active region, the source/drain region being in contact with the channel region;
a source/drain contact on the source/drain region and being connected to the source/drain region;
a source/drain via contact protruding from a first upper surface of the source/drain contact in a vertical direction, the source/drain via contact being integrally connected to the source/drain contact; and
a source/drain contact extension in contact with the first upper surface of the source/drain contact, the source/drain contact extension being spaced apart from the source/drain via contact in a second lateral direction, the source/drain contact extension having a second upper surface that is at a second vertical level,
wherein the second lateral direction is perpendicular to the first lateral direction, and a first vertical level of the first upper surface is between the second vertical level and the source/drain region in the vertical direction.

2. The integrated circuit device of claim 1, wherein the source/drain contact, the source/drain via contact, and the source/drain contact extension comprise a same metal.

3. The integrated circuit device of claim 1, comprising a first insulating barrier wall between the source/drain via contact and the source/drain contact extension, the first insulating barrier wall being in contact with the first upper surface of the source/drain contact.

4. The integrated circuit device of claim 1, comprising:
an insulating spacer between the gate line and the source/drain contact; and
a first insulating barrier wall covering sidewalls of the source/drain contact extension and surrounding the source/drain contact extension in both the first and second lateral directions,
wherein the first insulating barrier wall comprises
a first portion between the source/drain via contact and the source/drain contact extension, and
a second portion between the insulating spacer and the source/drain contact extension.

5. The integrated circuit device of claim 1, comprising a metal silicide film between the source/drain region and the source/drain contact,
wherein the source/drain contact extension is spaced apart from the metal silicide film in the vertical direction, and the source/drain contact is between the source/drain contact extension and the metal silicide film.

6. The integrated circuit device of claim 1, comprising a metal silicide film between the source/drain region and the source/drain contact,
wherein the source/drain contact extension comprises a portion in contact with the metal silicide film.

7. The integrated circuit device of claim 1, comprising a metal-containing conductive liner in contact with an upper surface of the source/drain via contact,
wherein the source/drain via contact comprises a first metal, and
wherein the metal-containing conductive liner comprises a second metal that is different from the first metal.

8. The integrated circuit device of claim 1, comprising:
a gate contact protruding from a third upper surface of the gate line in the vertical direction, the gate contact being integrally connected to the gate line; and
a gate extension in contact with the third upper surface of the gate line, the gate extension being spaced apart from the gate contact in the second lateral direction, the gate extension having a fourth upper surface,
wherein the fourth upper surface is at a higher vertical level than the third upper surface.

9. The integrated circuit device of claim 8, wherein the source/drain contact extension comprises a same material as the gate extension.

10. The integrated circuit device of claim 8, comprising a second insulating barrier wall between the gate contact and the gate extension, the second insulating barrier wall being in contact with the third upper surface of the gate line.

11. The integrated circuit device of claim 8, comprising:
an insulating spacer between the gate line and the source/drain contact; and
a second insulating barrier wall covering sidewalls of the gate extension and surrounding the gate extension in both the first and second lateral directions,
wherein the second insulating barrier wall comprises
a first portion between the gate contact and the gate extension, and
a second portion between the insulating spacer and the gate extension.

12. The integrated circuit device of claim 1, comprising:
a gate contact protruding from a third upper surface of the gate line in the vertical direction, the gate contact being integrally connected to the gate line;
a gate extension in contact with the third upper surface of the gate line, the gate extension being spaced apart from the gate contact in the second lateral direction, the gate extension having a fourth upper surface, wherein the fourth upper surface is at a higher vertical level than the third upper surface;
a first metal-containing conductive liner in contact with an upper surface of the source/drain via contact; and
a second metal-containing conductive liner in contact with an upper surface of the gate contact,
wherein the source/drain contact extension comprises a same material as the gate extension, and
wherein the first metal-containing conductive liner comprises a same material as the second metal-containing conductive liner.

13. An integrated circuit device comprising:
a pair of fin-type active regions each extending in a first lateral direction, the pair of fin-type active regions being parallel to each other;
a plurality of channel regions on the pair of fin-type active regions;
a plurality of gate lines extending in a second lateral direction on the pair of fin-type active regions, wherein the second lateral direction is perpendicular to the first lateral direction;
a pair of source/drain regions on the pair of fin-type active regions;
a source/drain contact on at least one source/drain region of the pair of source/drain regions, the source/drain contact being connected to the at least one source/drain region;
a source/drain via contact protruding from a first upper surface of the source/drain contact in a vertical direction, the source/drain via contact being integrally connected to the source/drain contact; and
a source/drain contact extension in contact with the first upper surface of the source/drain contact, the source/drain contact extension being spaced apart from the source/drain via contact in the second lateral direction, the source/drain contact extension having a second upper surface that is at a second vertical level, wherein a first vertical level of the first upper surface is between the second vertical level and the source/drain region in the vertical direction.

14. The integrated circuit device of claim 13, wherein the pair of source/drain regions comprise a first source/drain region on a first fin-type active region of the pair of fin-type active regions and a second source/drain region on a second fin-type active region of the pair of fin-type active regions, and
wherein the source/drain contact is connected to each of the first source/drain region and the second source/drain region.

15. The integrated circuit device of claim 13, comprising a first insulating barrier wall between the source/drain via contact and the source/drain contact extension, the first insulating barrier wall being in contact with the first upper surface of the source/drain contact,
wherein the first insulating barrier wall covers both sidewalls of the source/drain contact extension in the first lateral direction and both sidewalls of the source/drain contact extension in the second lateral direction.

16. The integrated circuit device of claim 13, comprising at least one metal silicide film between the at least one source/drain region and the source/drain contact,
wherein the source/drain contact extension is spaced apart from the at least one metal silicide film in the vertical direction, and the source/drain contact is between the source/drain contact extension and the at least one metal silicide film.

17. The integrated circuit device of claim 13, comprising at least one metal silicide film between the at least one source/drain region and the source/drain contact,
wherein the source/drain contact extension comprises a portion in contact with the at least one metal silicide film.

18. The integrated circuit device of claim 13, comprising:
a gate contact protruding in the vertical direction from a third upper surface of a first gate line of the plurality of gate lines, the gate contact being integrally connected to the first gate line;
a gate extension in contact with the third upper surface of the first gate line, the gate extension being spaced apart from the gate contact in the second lateral direction, the gate extension having a fourth upper surface that is at a higher vertical level than the third upper surface;
a first metal-containing conductive liner in contact with an upper surface of the source/drain via contact; and
a second metal-containing conductive liner in contact with an upper surface of the gate contact,
wherein the source/drain contact extension comprises a same material as the gate extension, and
wherein the first metal-containing conductive liner comprises a same material as the second metal-containing conductive liner.

19. An integrated circuit device comprising:
a fin-type active region extending in a first lateral direction;
a channel region on the fin-type active region;
a gate line surrounding the channel region;
a source/drain region on the fin-type active region, the source/drain region being in contact with the channel region;
a source/drain contact on the source/drain region, the source/drain contact being connected to the source/drain region;
a source/drain via contact protruding from a first upper surface of the source/drain contact in a vertical direction, the source/drain via contact being integrally connected to the source/drain contact;
a source/drain contact extension in contact with the first upper surface of the source/drain contact, the source/drain contact extension being spaced apart from the source/drain via contact in a second lateral direction, the source/drain contact extension having a second upper surface that is at a second vertical level, wherein the second lateral direction is perpendicular to the first lateral direction, and a first vertical level of the first upper surface is between the second vertical level and the source/drain region in the vertical direction;
a gate contact protruding from a third upper surface of the gate line in the vertical direction, the gate contact being integrally connected to the gate line; and
a gate extension in contact with the third upper surface of the gate line, the gate extension being spaced apart from the gate contact in the second lateral direction, the gate extension having a fourth upper surface that is at a higher vertical level than the third upper surface.

20. The integrated circuit device of claim 19, comprising:
a first metal-containing conductive liner in contact with an upper surface of the source/drain via contact; and
a second metal-containing conductive liner in contact with an upper surface of the gate contact,
wherein the source/drain contact extension comprises a same metal as the gate extension, and
wherein the first metal-containing conductive liner comprises a same conductive metal nitride as the second metal-containing conductive liner.
